(19) United States
(12) Patent Application Publication
(10) Pub. No.: US 2023/0301059 A1
(43) Pub. Date: Sep. 21, 2023

(54) SILICON NANO SHEET THREE-DIMENSIONAL HORIZONTAL MEMORY WITH ALL-AROUND METAL STORAGE CAPACITOR

(71) Applicant: Tokyo Electron Limited, Tokyo (JP)

(72) Inventors: H. Jim FULFORD, Marianna, FL (US); Mark I. GARDNER, Cedar Creek, TX (US); Partha MUKHOPADHYAY, Oviedo, FL (US)

(73) Assignee: Tokyo Electron Limited, Tokyo (JP)

(21) Appl. No.: 17/959,771

(22) Filed: Oct. 4, 2022

Related U.S. Application Data
(60) Provisional application No. 63/320,472, filed on Mar. 16, 2022.

(51) Int. Cl. H01L 27/108

(52) U.S. Cl. CPC H01L 27/10805; H01L 27/1085; H01L 27/10873

(57) ABSTRACT

Aspects of the present disclosure provide a semiconductor structure. For example, the semiconductor structure can include a lower transistor including a lower channel that is elongated horizontally; an upper transistor vertically stacked over the lower transistor and including an upper channel that is elongated horizontally; a lower metal capacitor electrically connected to and horizontally elongated from the lower transistor, the lower metal capacitor including a first lower metal plate, a lower dielectric layer that surrounds the first lower metal plate, and a second lower metal plate that surrounds the lower dielectric layer; and an upper metal capacitor vertically stacked over the lower metal capacitor and electrically connected to and horizontally elongated from the upper transistor, the upper metal capacitor including a first upper metal plate, an upper dielectric layer that surrounds the first upper metal plate, and a second upper metal plate that surrounds the upper dielectric layer.

### INCORPORATION BY REFERENCE

This present disclosure claims the benefit of U.S. Provisional Application No. 63/320,472, “SILICON NANO SHEET 3D HORIZONTAL MEMORY WITH ALL-AROUND METAL STORAGE CAPACITOR” filed on Mar. 16, 2022, which is incorporated herein by reference in its entirety.

### FIELD OF THE INVENTION

This disclosure relates to microelectronic devices including semiconductor devices, transistors, and integrated circuits, including methods of microfabrication.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Aspects of the present disclosure provide a method for fabricating a semiconductor structure. For example, the method can include forming over a substrate a lower stack of alternating metal and dielectric layers that are parallel to a top surface of the substrate. The method can also include forming an upper stack of alternating metal and dielectric layers that are parallel to the top surface of the substrate. The upper stack can be vertically stacked over the lower stack. The method can also include forming a first opening through the upper stack and the lower stack until uncovering a top surface of the substrate. The method can also include forming within the first opening a lower transistor that is insulated from the substrate and an upper transistor that is vertically stacked over the lower transistor. The lower transistor can include a lower channel that is elongated horizontally and is in-plane with a first lower metal layer of the lower stack. The upper transistor can include an upper channel that is elongated horizontally and is in-plane with a first upper metal layer of the upper stack. The method can also include removing the dielectric layers of the upper stack and the lower stack within a metal capacitor opening area that is separated from the first opening at a distance to uncover the first lower metal layer of the lower stack and the first upper metal layer of the upper stack that are a first lower metal plate of a lower metal capacitor and a first upper metal plate of an upper metal capacitor, respectively. The method can also include surrounding the first lower metal plate and the first upper metal plate with a dielectric layer, and surrounding the dielectric layer with a first metal material that forms a second lower metal plate of the lower metal capacitor and a second upper metal plate of the upper metal capacitor. In an embodiment, the lower transistor can be narrower than the lower metal capacitor horizontally.

In an embodiment, the second lower metal plate of the lower metal capacitor and the second upper metal plate of the upper metal capacitor can be electrically connected to each other.

In an embodiment, the lower transistor can further include a lower gate region that surrounds the lower channel, and the upper transistor can further include an upper gate region that surrounds the upper channel. For example, the upper gate region and the lower gate region can be electrically connected to each other. In an embodiment, the lower transistor and the upper transistor can be formed by: epitaxially growing a first single crystal material on the substrate within the first opening; epitaxially growing a second single crystal material over the first single crystal material to maintain single crystallinity, the second single crystal material being etched selectively with respect to the first single crystal material; epitaxially growing the lower channel of the lower transistor over the second single crystal material, the lower channel covering a lateral side of the first lower metal layer of the lower stack; epitaxially growing a third single crystal material over the lower channel, the third single crystal material being etched selectively with respect to the first single crystal material; epitaxially growing the upper channel of the upper transistor over the third single crystal material, the upper channel covering a lateral side of the first upper metal layer of the upper stack; epitaxially growing a fourth single crystal material over the upper channel, the fourth single crystal material being etched selectively with respect to the first single crystal material; etching and removing the first single crystal material and replacing with an insulating material; etching the second single crystal material, the third single crystal material and the fourth single crystal material to uncover the lower channel and the upper channel; forming the lower gate region and the upper gate region that surround the lower channel and the upper channel, respectively; and filling the first opening with a second metal material. For example, the second single crystal material, the third single crystal material and the fourth single crystal material can be the same. As another example, the second single crystal material can include SiGe30. In some embodiments, the first single crystal material can include SiGe90.

In an embodiment, the method can further include forming one or more lower pillars that separate the second lower metal plate of the lower metal capacitor. For example, the lower pillars can be formed by: removing a portion of a lower dielectric layer of the lower stack that is under the first lower metal layer; and filling a dielectric material in a space that is generated after the portion of the lower dielectric layer of the lower stack is removed, the dielectric material being etched selectively with respect to the lower dielectric layer of the lower stack.

Aspects of the present disclosure also provide a semiconductor structure. For example, the semiconductor structure can include a lower transistor including a lower channel that is elongated horizontally, and an upper transistor vertically stacked over the lower transistor and including an upper channel that is elongated horizontally. The semiconductor structure can also include a lower metal capacitor electrically connected to and horizontally elongated from the lower transistor, the lower metal capacitor including a first lower metal plate, a lower dielectric layer that surrounds the first lower metal plate, and a second lower metal plate that surrounds the lower dielectric layer. The semiconductor structure can also include an upper metal capacitor vertically stacked over the lower metal capacitor and electrically connected to and horizontally elongated from the upper transistor, the upper metal capacitor including a first upper metal plate, an upper dielectric layer that surrounds the first upper metal plate, and a second upper metal plate that surrounds the upper dielectric layer.

In an embodiment, the first lower metal plate of the lower metal capacitor can be electrically connected to and in-plane with the lower channel of the lower transistor, and the first upper metal plate of the upper metal capacitor can be electrically connected to and in-plane with the upper channel of the upper transistor. In another embodiment, the second upper metal plate and the second lower metal plate can be electrically connected to each other.

In an embodiment, the lower transistor can further include a lower gate region that surrounds the lower channel, and the upper transistor can further include an upper gate region that surrounds the upper channel. For example, the upper gate region and the lower gate region can be electrically connected to each other. As another example, the semiconductor structure can further include a metal layer that surrounds the lower gate region of the lower transistor and the upper gate region of the upper transistor.

In an embodiment, the lower dielectric layer of the lower metal capacitor can be in-plane with the lower gate region of the lower transistor, and the upper dielectric layer of the upper metal capacitor can be in-plane with the upper gate region of the upper transistor. In another embodiment, the lower metal capacitor can further include one or more lower pillars that separate the second lower metal plate.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the present disclosure and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A-19A show schematic top views of various intermediary steps of a first exemplary method for fabricating a semiconductor structure according to the some embodiments of the present disclosure;

FIGS. 1B-19B show cross-sectional views of the semiconductor structure along cut lines BB′ shown in FIGS. 1A-19A, respectively, according to the some embodiments of the present disclosure;

FIGS. 3C-19C show cross-sectional views of the semiconductor structure along cut lines CC′ shown in FIGS. 3A-19A, respectively, according to the some embodiments of the present disclosure;

FIGS. 3D-19D show cross-sectional views of the semiconductor structure along cut lines DD′ shown in FIGS. 3A-19A, respectively, according to the some embodiments of the present disclosure;

FIGS. 20A-41A show schematic top views of various intermediary steps of a second exemplary method for fabricating a semiconductor structure according to the some embodiments of the present disclosure;

FIGS. 20B-41B show cross-sectional views of the semiconductor structure along cut lines BB′ shown in FIGS. 20A-41A, respectively, according to the some embodiments of the present disclosure;

FIGS. 25C-41C show cross-sectional views of the semiconductor structure along cut lines CC′ shown in FIGS. 25A-41A, respectively, according to the some embodiments of the present disclosure; and

FIGS. 25D-41D show cross-sectional views of the semiconductor structure along cut lines DD′ shown in FIGS. 25A-41A, respectively, according to the some embodiments of the present disclosure.

### DETAILED DESCRIPTION

Three-dimensional (3D) integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips, e.g., central processing units (CPUs), graphics processing units (GPUs), field programmable gate arrays (FPGAs) and system on a chip (SoC), is being pursued.

Techniques herein integrate a novel 3D horizontal memory cell with sequential 3D vertical stacking. Techniques include providing horizontal DRAM access with silicon nanosheet transistor and metal capacitor. Embodiments include all-around metal capacitor. Embodiments are highly suitable for hierarchical design of n-number stacks. All gate metals are shorted vertically with individual nanosheet pass transistors. All non-terminal capacitor metal (the terminal not connected to nanosheet) has common ground connection.

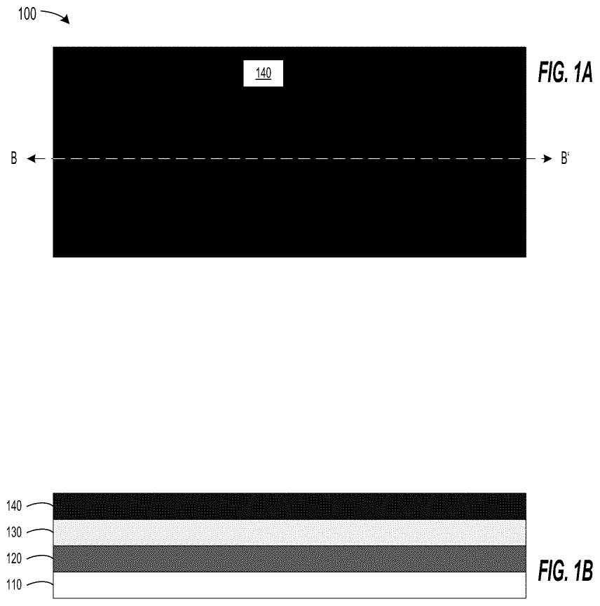

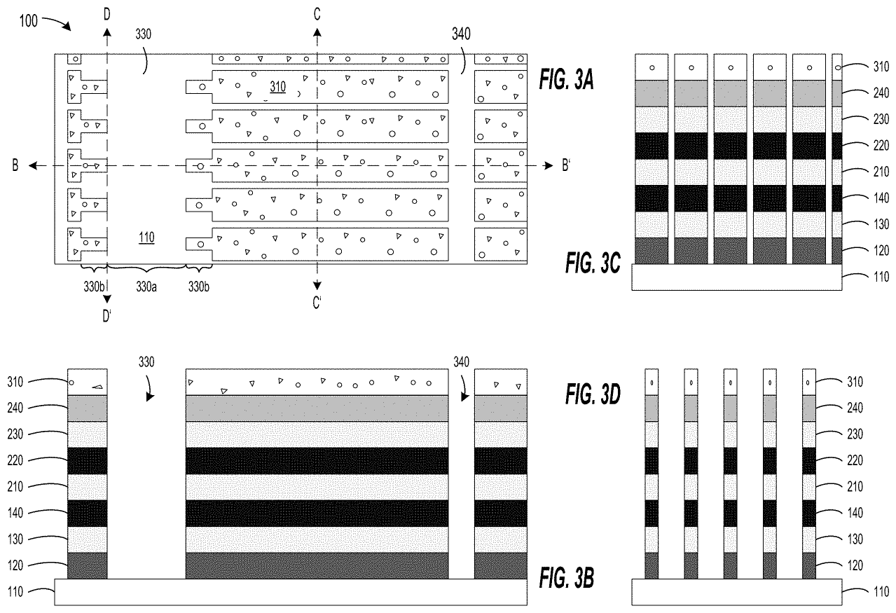

FIGS. 1A-19A show schematic top views of various intermediary steps of a first exemplary method for fabricating a semiconductor structure 100 according to the some embodiments of the present disclosure. The semiconductor structure 100 can include 3D silicon nanosheet memories with metal capacitors. For example, the semiconductor structure 100 can include one or more vertically stacked horizontal dynamic random access memories (DRAMs) access with silicon nanosheet transistors and metal capacitors. In an embodiment, all gate metal are shorted vertically with individual nanosheet transistors, and all non-terminal capacitor metal plates, i.e., the terminals not connected to the nanosheet transistors, have common ground connection. FIGS. 1B-19B show cross-sectional views of the semiconductor structure 100 along cut lines BB′ shown in FIGS. 1A-19A, respectively, according to the some embodiments of the present disclosure. FIGS. 3C-19C show cross-sectional views of the semiconductor structure 100 along cut lines CC′ shown in FIGS. 3A-19A, respectively, according to the some embodiments of the present disclosure. FIGS. 3D-19D show cross-sectional views of the semiconductor structure 100 along cut lines DD′ shown in FIGS. 3A-19A, respectively, according to the some embodiments of the present disclosure.

As shown in FIGS. 1A and 1B, a substrate 110 is provided. The substrate 110 can include a Si or SiGe substrate. In an embodiment, the substrate 110 can be a lightly doped p-type silicon substrate. A first dielectric layer 120, e.g., made of a first dielectric material, can be deposited and formed on the substrate 110. In an embodiment, the first dielectric layer 120 can be comparatively thick. A second dielectric layer 130 can be deposited and formed on the first dielectric layer 120. In an embodiment, the second dielectric layer 130 can be made of a second dielectric material that is etched selectively with respect to the first dielectric material. Then, a first metal layer 140 made of a first metal material can be deposited and formed on the second dielectric layer 130.

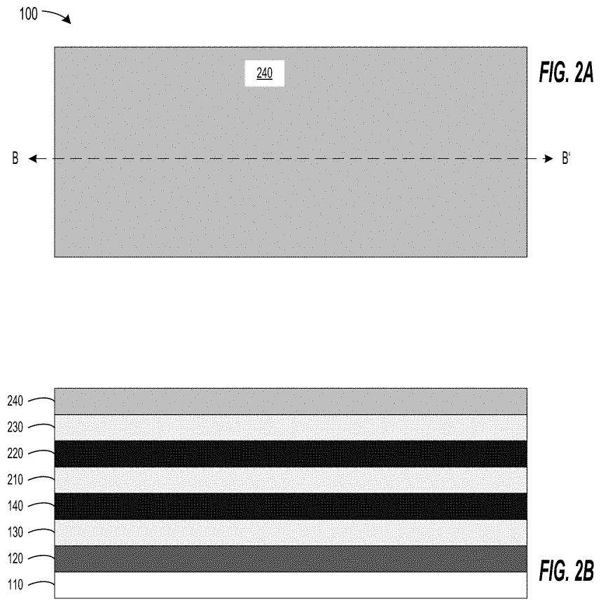

As shown in FIGS. 2A and 2B, a third dielectric layer 210 and a second metal layer 220 can be deposited and formed on the first metal layer 140 sequentially. In an embodiment, the second metal layer 220 can be made of the first metal material. The third dielectric layer 210 can insulate the first metal layer 140 from the second metal layer 220. A fourth dielectric layer 230 can then be deposited and formed on the second metal layer 220. In an embodiment, the second dielectric layer 130, the third dielectric layer 210 and the fourth dielectric layer 230 can be made of the same material, i.e., the second dielectric material. Then, a fifth dielectric layer 240 can be deposited and formed on the fourth dielectric layer 230. In an embodiment, the fifth dielectric layer 240 can be made of a third dielectric material that is etched selectively with respect to the first and second dielectric materials. In the example embodiment, two stacks of metal and dielectric layers vertically stacked over each other are shown. In some embodiments, the semiconductor structure 100 can include n stacks of metal and dielectric layers that are vertically stacked over one another.

As shown in FIGS. 3A-3D, an etch mask or photo resist layer 310, e.g., a DRAM slicing mask, is formed on the fifth dielectric layer 240, and the semiconductor structure 100 is directionally etched through the stacks of metal and dielectric layers to uncover a top surface (e.g., a working surface) of the substrate 110, thus forming a plurality of semiconductor slices that are separated from one another, each of which has a nanosheet transistor opening area 330 and a first metal capacitor opening area 340. In an embodiment, the nanosheet transistor opening area 330 is for nanosheet access transistors to be formed therein, and includes a central portion 330a and an extended portion 330b.

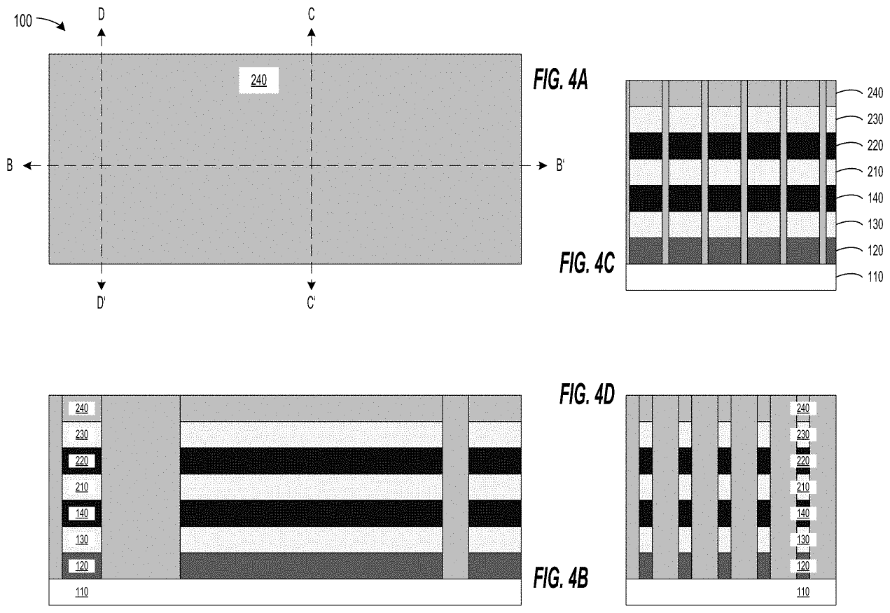

As shown in FIGS. 4A-4D, the etch mask 310 is stripped off and removed, and the nanosheet transistor opening area 330 and the first metal capacitor opening area 340 are filled with a dielectric material, e.g., the second dielectric material, of which the fifth dielectric layer 240 is made.

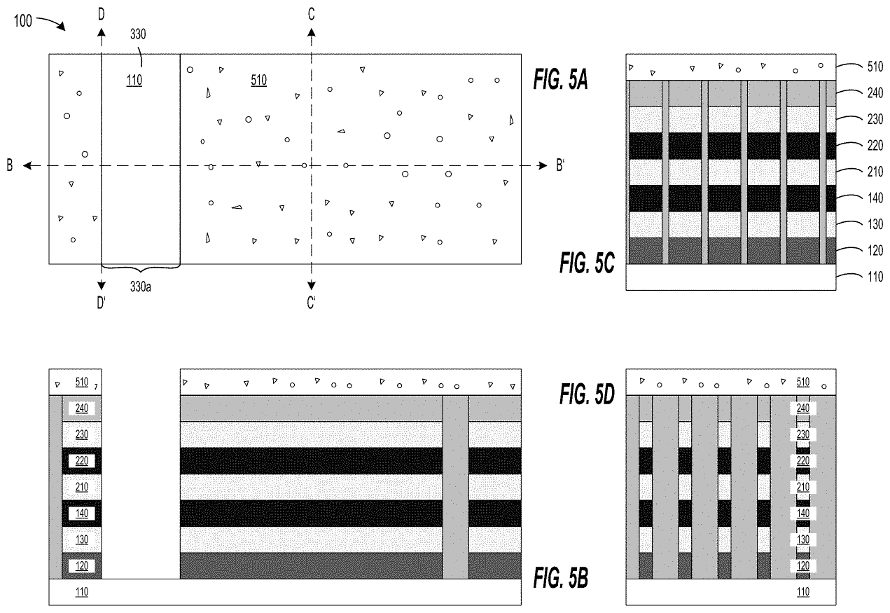

As shown in FIGS. 5A-5D, an etch mask or photo resist layer 510 is deposited and formed on the fifth dielectric layer 240, with a portion of the fifth dielectric layer 240 that is filled in the central portion 330a of the nanosheet transistor opening area 330 uncovered, and then the semiconductor structure 100 is directionally etched through the stacks of metal and dielectric layers within the central portion 330a of the nanosheet transistor opening area 330 to uncover the top surface of the substrate 110.

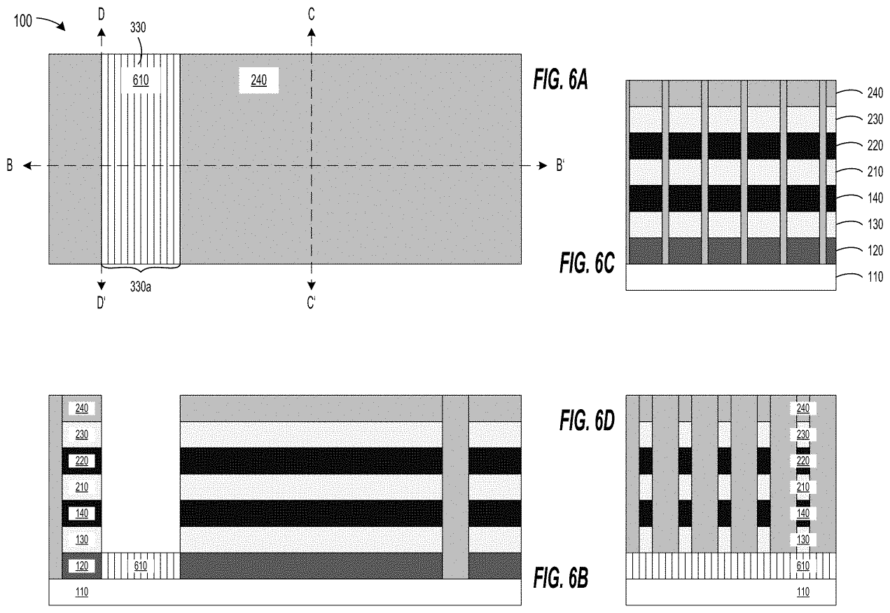

As shown in FIGS. 6A-6D, a first SiGe layer 610, e.g., SiGe90, is epitaxially grown on the uncovered top surface of the lightly doped p-type silicon substrate 110. In an embodiment, the first SiGe layer 910 is to cover a lateral surface of the first dielectric layer 120. The first SiGe layer 610 is used to replace with an insulation layer in future process steps to keep the nanosheet transistors isolated from the substrate 110.

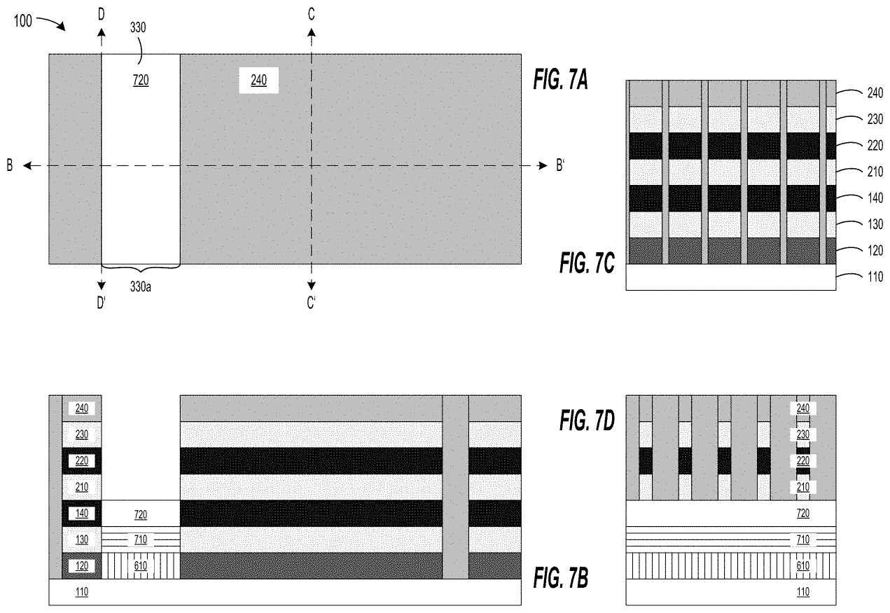

As shown in FIGS. 7A-7D, a second SiGe layer 710, e.g., SiGe30, that is different from the first SiGe layer 910, is epitaxially grown on the first SiGe layer 610 to maintain the single crystallinity. The second SiGe layer 710 and the first SiGe layer 610 can be etched selectively with respect to each other. In the example embodiment, the second SiGe layer 710 can be leveled with the second dielectric layer 130. In some embodiments, the second SiGe layer 710 can cover a portion of a lateral surface of the second dielectric layer 130. A first lightly doped p-type silicon layer 720 can be epitaxially grown on the second SiGe layer 710. In an embodiment, the first lightly doped p-type silicon layer 720 has a thickness such that the first lightly doped p-type silicon layer 720 can cover and touch the first metal layer 140 entirely. In another embodiment, the first lightly doped p-type silicon layer 720 can be thicker to further cover a portion of the third dielectric layer 210 and/or a portion of the second dielectric layer 130.

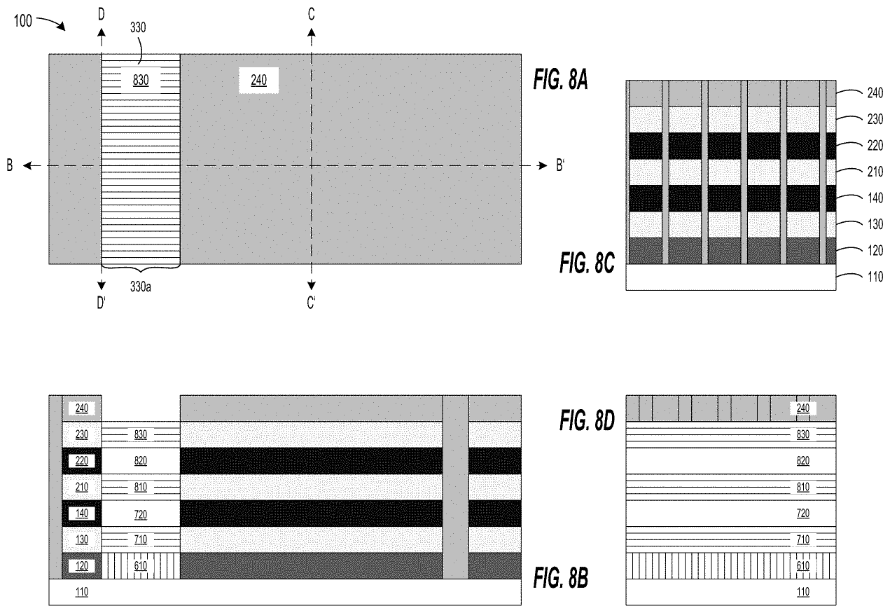

As shown in FIGS. 8A-8D, the epitaxially-grown of SiGe30, lightly doped p-type silicon and SiGe30 layers of the semiconductor structure 100 can be finished by following the same strategy as illustrated in FIGS. 6A-6D and 7A-7D. For example, a third SiGe layer 810, e.g., made of SiGe30, can be deposited and formed on the first lightly doped p-type silicon layer 720, a second lightly doped p-type silicon layer 820 can be deposited and formed on the third SiGe layer 810, and a fourth SiGe layer 830, e.g., made of SiGe30, can be deposited and formed on the second lightly doped p-type silicon layer 820. In an embodiment, the third SiGe layer 810, the second lightly doped p-type silicon layer 820 and the fourth SiGe layer 830 can be leveled with the third dielectric layer 210, the second metal layer 220 and the fourth dielectric layer 230, respectively. In an embodiment, the second lightly doped p-type silicon layer 820 has a thickness such that the second lightly doped p-type silicon layer 820 can cover and touch the second metal layer 220 entirely. In another embodiment, the second lightly doped p-type silicon layer 820 can be thicker to further cover a portion of the fourth dielectric layer 230 and/or a portion of the third dielectric layer 210. For n stacks, the SiGe30 layer and the lightly doped p-type silicon layer can be repeated accordingly. In the example embodiment, the semiconductor structure 100 includes only one of the SiGe90, i.e., the first SiGe layer 610, which is formed at the bottom most within the nanosheet transistor opening area 330. In an embodiment, the semiconductor structure 100 can include more than one of the SiGe90 and one or more than one of the SiGe90 can be inserted in between the SiGe30 if any discontinuity is needed in the semiconductor structure 100.

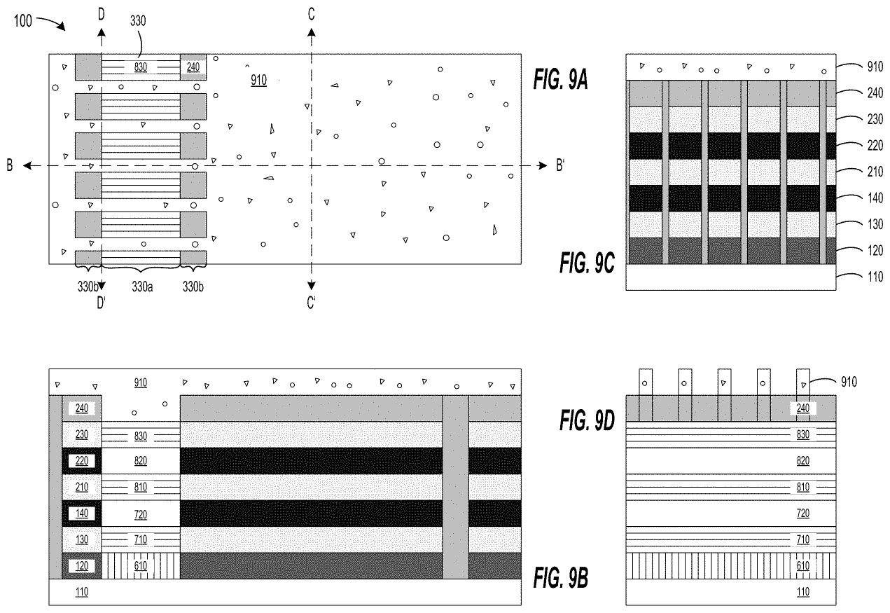

As shown in FIGS. 9A-9D, an etch mask or photo resist layer 910, e.g., a DRAM slicing mask, is formed on the fifth dielectric layer 240, with the nanosheet transistor opening area 330, including the central portion 330a and the extended portion 330b, uncovered.

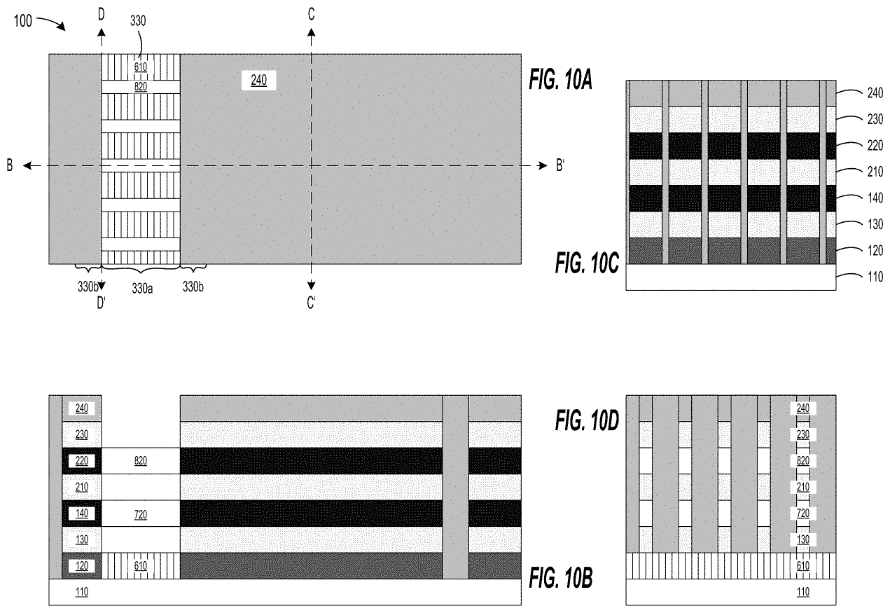

As shown in FIGS. 10A-10D, the semiconductor structure 100 is directionally etched to remove the SiGe30, i.e., the second SiGe layer 710, the third SiGe layer 810 and the fourth SiGe layer 830, with the first lightly doped p-type silicon layer 720, the second lightly doped p-type silicon layer 820, and the SiGe90, i.e., the first SiGe layer 610, intact. In an embodiment, for each suitability the final SiGe30 needs not be etched all the way. For example, partial etching is enough to access the SiGe30. In an embodiment, the SiGe30 can be removed by vapor-phase isotropic etching.

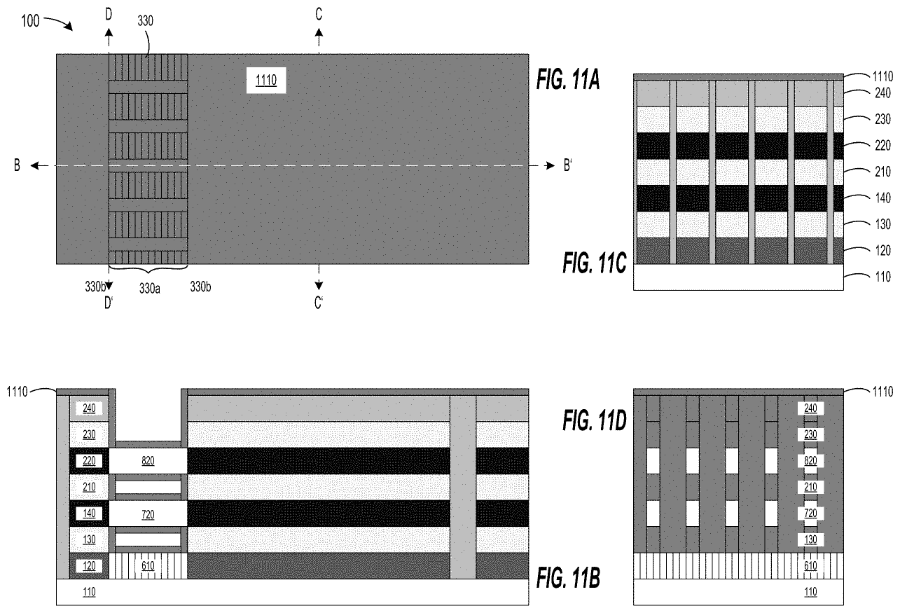

As shown in FIGS. 11A-11D, a thin first high-k dielectric layer 1110 is formed in a conformal deposition process, e.g., an atomic layer deposition (ALD) process, to surround the first lightly doped p-type silicon layer 720 and the second lightly doped p-type silicon layer 820, which are used as channels of the nanosheet transistors of the semiconductor structure 100. The ALD process is often performed at a low temperature, which makes less or even no damages on the components already fabricated, and can provide ultra-thin nano-layers in a precise manner on the first lightly doped p-type silicon layer 720 and the second lightly doped p-type silicon layer 820.

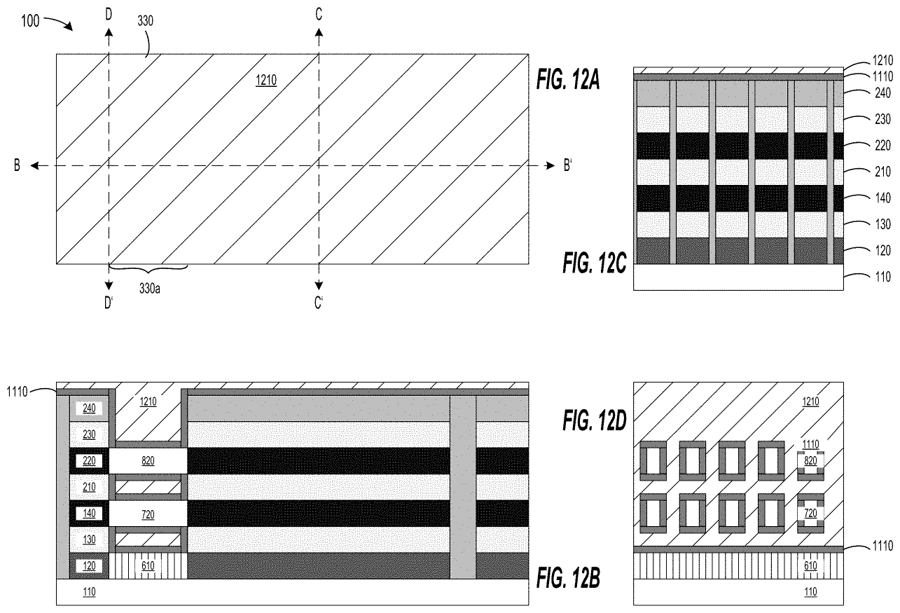

As shown in FIGS. 12A-12D, a third metal layer 1210 is deposited and formed on the first high-k dielectric layer 1110. In an embodiment, the third metal layer 1210 can be made of a third metal material that is different from the first metal material.

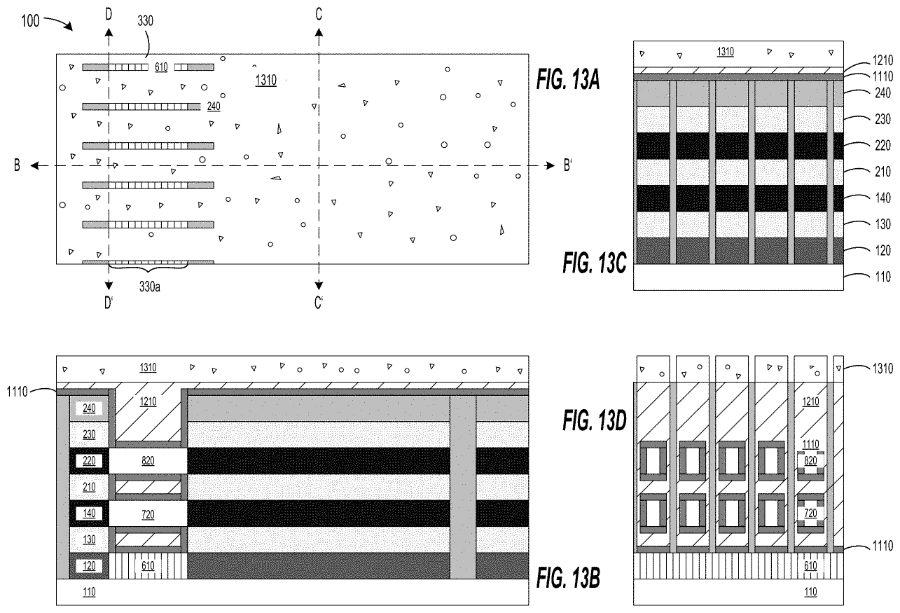

As shown in FIGS. 13A-13D, an etch mask or photo resist layer 1310, e.g., a DRAM slicing mask, is formed on the third metal layer 1210, and the semiconductor structure 100 is directionally etched through the third metal layer 1210 and the first high-k dielectric layer 1110 to uncover the SiGe90, i.e., the first SiGe layer 610. This etch opens access to the first SiGe layer 610.

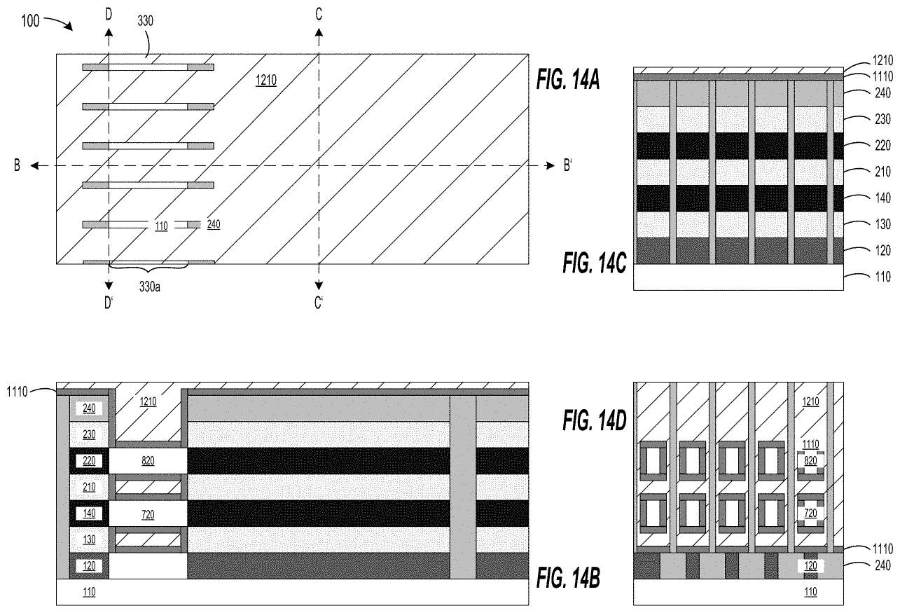

As shown in FIGS. 14A-14D, the SiGe90, i.e., the first SiGe layer 610, is etched and removed. The etch mask 1310 can also be stripped off and removed.

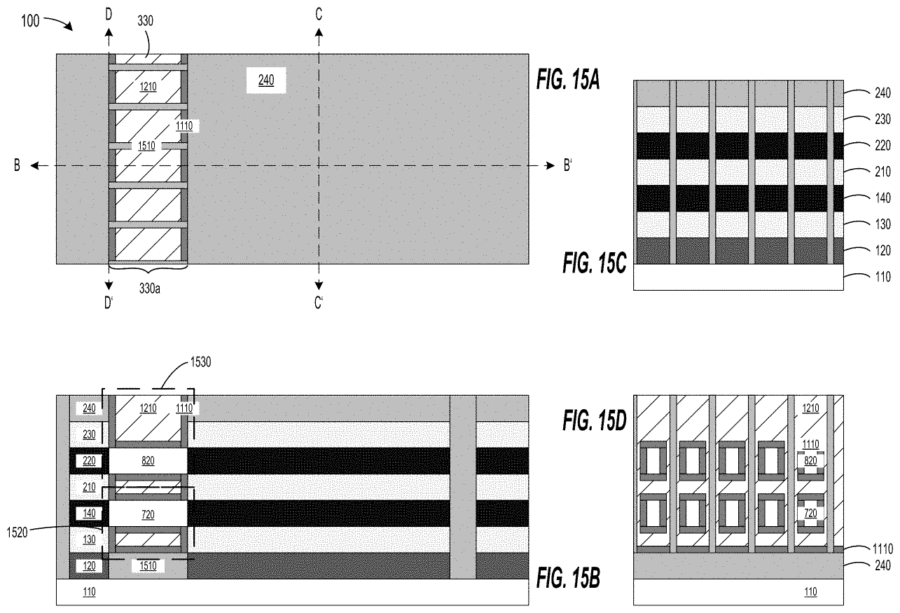

As shown in FIGS. 15A-15D, a dielectric layer 1510, e.g., made of the second dielectric material, fills a space that is generated after the SiGe90, i.e., the first SiGe layer 610, is removed. A chemical-mechanical polishing (CMP) process can then be performed to planarize the dielectric layer 1510, the third metal layer 1210 and the first high-k dielectric layer 1110.

The semiconductor structure 100 thus fabricated can include a (gate-all-around (GAA)) lower (or first) nanosheet transistor 1520 and an (GAA) upper (or second) nanosheet transistor 1530 that is stacked over the lower nanosheet transistor 1520. The lower nanosheet transistor 1520 includes a channel, i.e., the first lightly doped p-type silicon layer 720, a gate region, i.e., the first high-k dielectric layer 1110, that surrounds the channel and is surrounded by the third metal layer 1210, which can act as a gate electrode of the lower nanosheet transistor 1520, and source/drain (S/D) regions, i.e., two ends of the first lightly doped p-type silicon layer 720, that are electrically connected to the first metal layer 140, which can act as S/D electrodes of the lower nanosheet transistor 1520. The dielectric layer 1510 can insulate the lower nanosheet transistor 1520 from the substrate 110. The upper nanosheet transistor 1530 includes a channel, i.e., the second lightly doped p-type silicon layer 820, a gate region, i.e., the first high-k dielectric layer 1110, that surrounds the channel and is surrounded by the third metal layer 1210, which can act as a gate electrode of the upper nanosheet transistor 1530, and source/drain regions, i.e., two ends of the second lightly doped p-type silicon layer 820, that are electrically connected to the second metal layer 220, which can act as S/D electrodes of the upper nanosheet transistor 1530. The gate regions of the lower nanosheet transistor 1520 and the upper nanosheet transistor 1530 are shorted by the third metal layer 1210. Since the lower nanosheet transistor 1520 and the upper nanosheet transistor 1530 are single crystal silicon, high performance Idₛₐₜ and robust Id_{off} can be achieved.

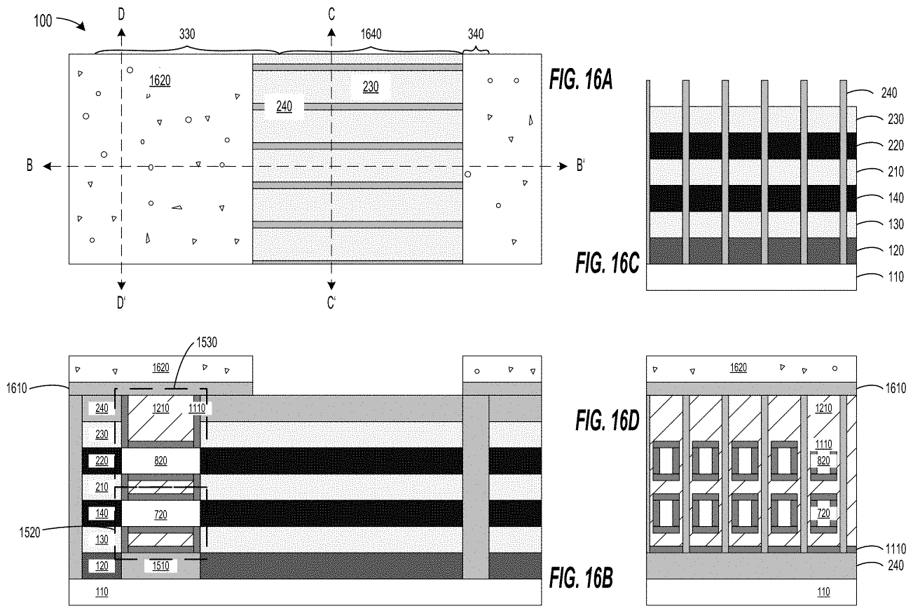

As shown in FIGS. 16A-16D, a hard mask or photo resist layer 1610, e.g., made of the second dielectric material, is formed on the semiconductor structure 100 to cover the fifth dielectric layer 240, the third metal layer 1210 and the first high-k dielectric layer 1110. An etch mask 1620, e.g., a DRAM capacitor mask, is formed on the hard mask 1610, with a portion of the hard mask 1610 uncovered that is within a second metal capacitor opening area 1640 that is between the nanosheet transistor opening area 330 and the first metal capacitor opening area 340 and is adjacent to the first metal capacitor opening area 340. In an embodiment, the second metal capacitor opening area 1640 can be used for metal capacitors to be formed therein, which can be shorted to a common ground. In an embodiment, the second metal capacitor opening area 1640 can be wider than the nanosheet transistor opening area 330 for the metal capacitors of the semiconductor structure 100 to have a higher capacitor value. Then, the semiconductor structure 100 within the second metal capacitor opening area 1640 is directionally etched to etch the hard mask 1610. In an embodiment, this etch can continue until uncovering the top surface of the substrate 110.

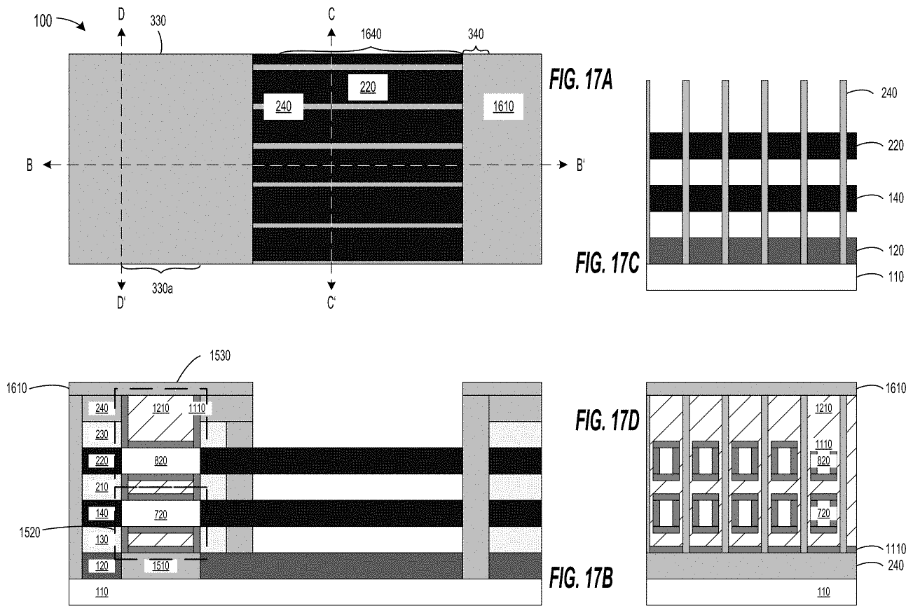

As shown in FIGS. 17A-17D, the etch mask 1620 is stripped off and removed, and the fourth dielectric layer 230, the third dielectric layer 210 and the second dielectric layer 130 are etched and removed.

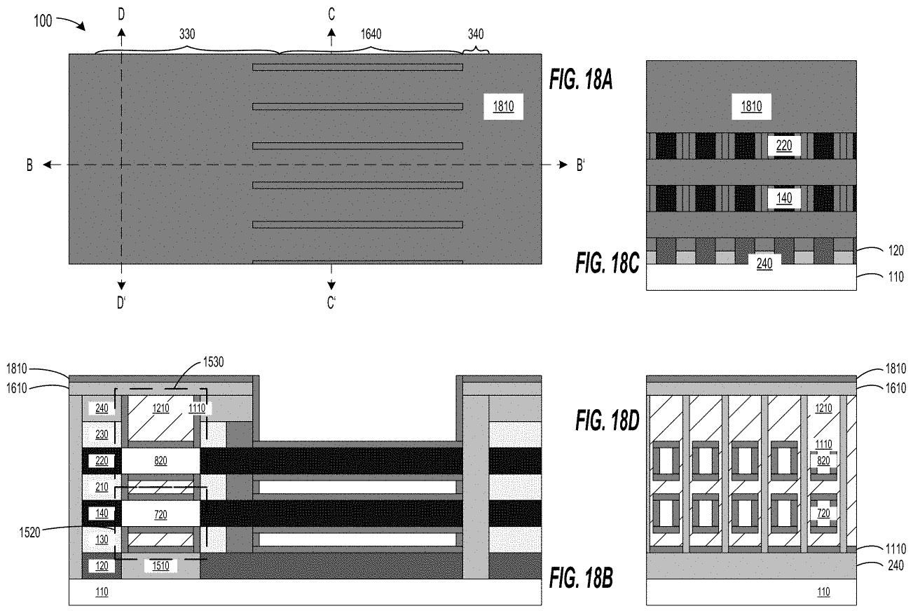

As shown in FIGS. 18A-18D, a thin second high-k dielectric layer 1810 is formed in a conformal deposition process to surround the first metal layer 140 and the second metal layer 220 within the second metal capacitor opening area 1640. The ALD process can provide ultra-thin nano-layers in a precise manner on the first metal layer 140 and the second metal layer 220.

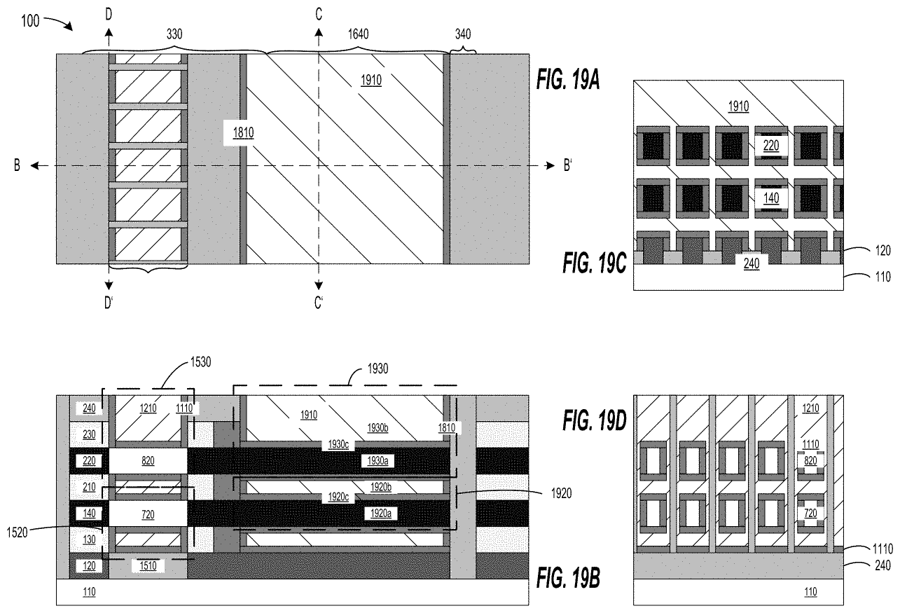

As shown in FIGS. 19A-19D, the hard mask 1610 is stripped off and removed, and a fourth metal layer 1910 is be deposited and formed to surround the second high-k dielectric layer 1810. In an embodiment, the fourth metal layer 1910 can be made of a second metal material that is different from the first and third metal materials. The CMP process can then be performed to planarize the fourth metal layer 1910 and the second high-k dielectric layer 1810.

The semiconductor structure 100 thus further fabricated can further include a lower metal capacitor 1920 and an upper metal capacitor 1930 that is stacked over the lower metal capacitor 1920. The lower metal capacitor 1920 is electrically connected to the lower nanosheet transistor 1520 horizontally, and includes a first lower metal plate 1920a, i.e., the first metal layer 140, that is electrically connected to the S/D electrodes of the lower nanosheet transistor 1520, a second lower metal plate (or non-terminal metal plate) 1920b, i.e., the fourth metal layer 1910, that is isolated by the third dielectric layer 210 from the lower nanosheet transistor 1520 and is not electrically connected to the lower nanosheet transistor 1520, and a lower dielectric layer 1920c, i.e., the second high-k dielectric layer 1810, that is sandwiched between the first lower metal plate 1920a and the second lower metal plate 1920b for storing electrical charges flowing from the lower nanosheet transistor 1520. The upper metal capacitor 1930 is electrically connected to the upper nanosheet transistor 1530 horizontally, and includes a first upper metal plate 1930a, i.e., the second metal layer 220, that is electrically connected to the S/D electrodes of the upper nanosheet transistor 1530, a second upper metal plate (or non-terminal metal plate) 1930b, i.e., the fourth metal layer 1910, that is isolated by the fifth dielectric layer 240 from the upper nanosheet transistor 1530 and is not electrically connected to the upper nanosheet transistor 1530, and an upper dielectric layer 1930c, i.e., the second high-k dielectric layer 1810, that is sandwiched between the first upper metal plate 1930a and the second upper metal plate 1930b for storing electrical charges flowing from the upper nanosheet transistor 1530. The non-terminal metal plates of the lower metal capacitor 1920 and the upper metal capacitor 1930, i.e., the second lower metal plate 1920b and the second upper metal plate 1930b, can be electrically connected, e.g., by the fourth metal layer 1910, and have common ground connection and be shorted to a common ground.

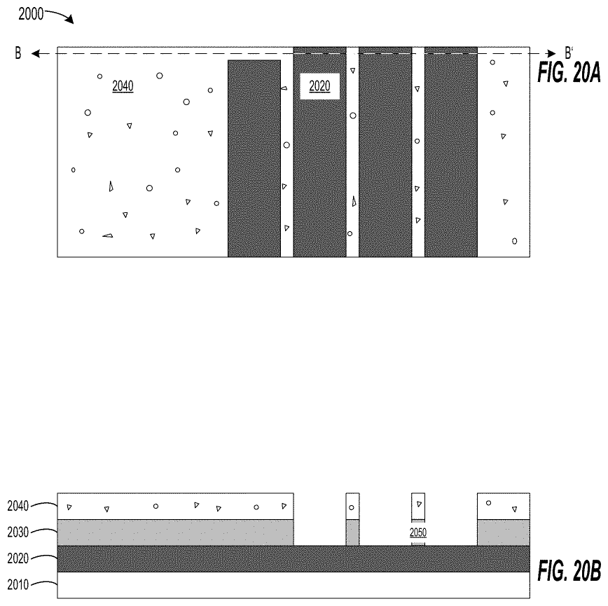

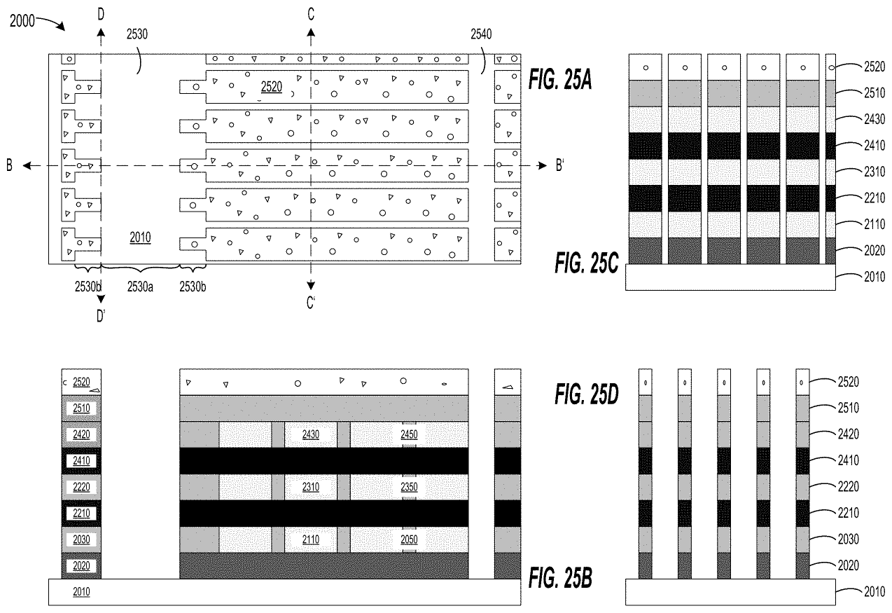

FIGS. 20A-41A show schematic top views of various intermediary steps of a second exemplary method for fabricating a semiconductor structure 2000 according to the some embodiments of the present disclosure. The semiconductor structure 2000 can also include 3D silicon nanosheet memories with metal capacitors. For example, the semiconductor structure 2000 can include one or more vertically stacked horizontal DRAMs access with silicon nanosheet transistors and metal capacitors. In an embodiment, all gate metal are shorted vertically with individual nanosheet transistors, and all non-terminal capacitor metal plates, i.e., the terminals not connected to the nanosheet transistors, have common ground connection. FIGS. 20B-41B show cross-sectional views of the semiconductor structure 2000 along cut lines BB′ shown in FIGS. 20A-41A, respectively, according to the some embodiments of the present disclosure. FIGS. 25C-41C show cross-sectional views of the semiconductor structure 2000 along cut lines CC′ shown in FIGS. 25A-41A, respectively, according to the some embodiments of the present disclosure. FIGS. 25D-41D show cross-sectional views of the semiconductor structure 2000 along cut lines DD′ shown in FIGS. 25A-41A, respectively, according to the some embodiments of the present disclosure.

As shown in FIGS. 20A and 20B, a substrate 2010 is provided. The substrate 110 can include a Si or SiGe substrate. In an embodiment, the substrate 2010 can be a lightly doped p-type silicon substrate. A first dielectric layer 2020, e.g., made of a first dielectric material, can be deposited and formed on the substrate 2010. In an embodiment, the first dielectric layer 2020 can be comparatively thick. A second dielectric layer 2030 can be deposited and formed on the first dielectric layer 2020. In an embodiment, the second dielectric layer 2030 can be made of a second dielectric material that is etched selectively with respect to the first dielectric material. An etch mask or photo resist layer 2040, e.g., a capacitor pillar mask, can be patterned and formed on the second dielectric layer 2030, and a portion of the second dielectric layer 2030 that is not covered by the etch mask 2040 is directionally etched to form lower pillars 2050. The lower pillars 2050 can provide support to structures that are formed thereover. In an embodiment, a portion of the first dielectric layer 2020 may also be directionally etched.

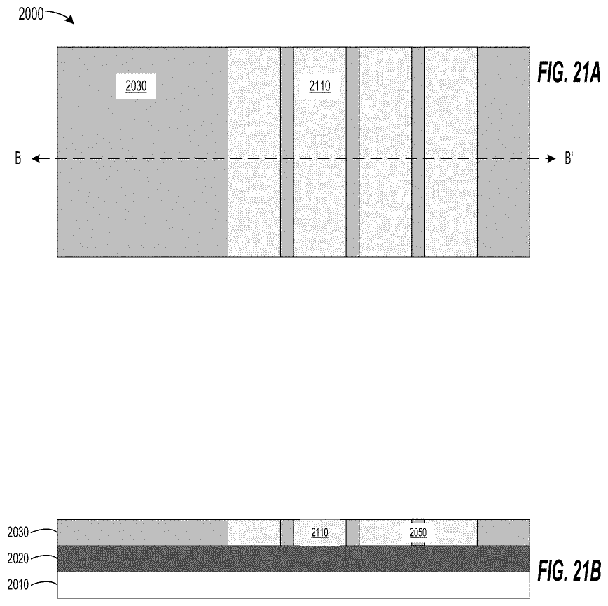

As shown in FIGS. 21A and 21B, the etch mask 2040 is stripped off and removed, and a third dielectric layer 2110 fills spaces that are generated after the portion of the second dielectric layer 2030 is removed. In an embodiment, the third dielectric layer 2130 can be made of a third dielectric material that is etched selectively with respect to the first and second dielectric materials. The CMP process can be performed to planarize the third dielectric layer 2110 and the second dielectric layer 2030.

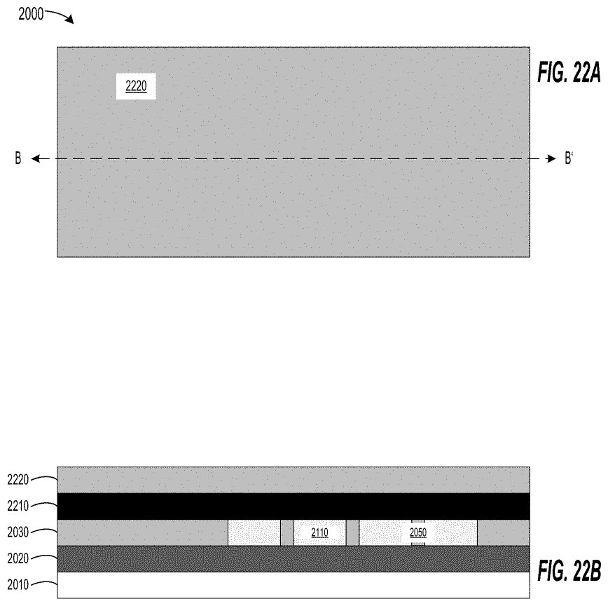

As shown in FIGS. 22A and 22B, a first metal layer 2210, e.g., made of a first metal material, is deposited and formed on the semiconductor structure 2000 to cover the second dielectric layer 2030 and the third dielectric layer 2110, and a comparatively thick fourth dielectric layer 2220, e.g., made of the second dielectric material, is deposited and formed on the first metal layer 2210.

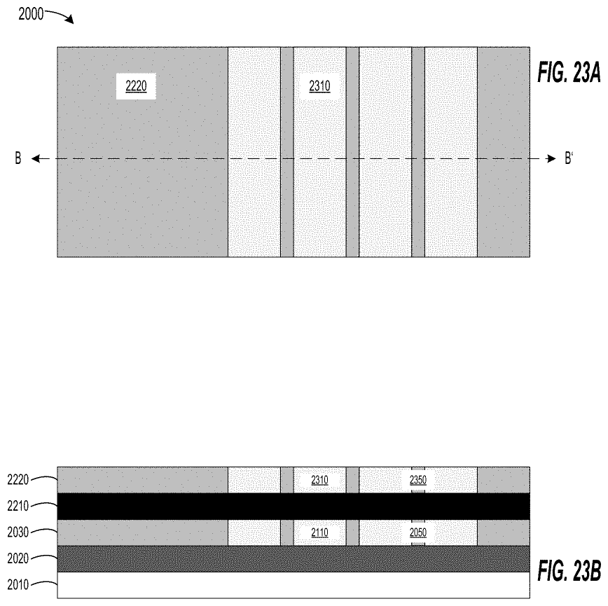

As shown in FIGS. 23A and 23B, the etch mask 2040 (shown in FIG. 20A) is formed on the fourth dielectric layer 2220, and a portion of the fourth dielectric layer 2220 that is not covered by the etch mask 2040 is directionally etched to form upper pillars 2350. The upper pillars 2350 can provide support to structures that are formed thereover. The etch mask 2040 is stripped off and removed, and a fifth dielectric layer 2310, e.g., made of the third dielectric material, can fill spaces that are generated after the portion of the fourth dielectric layer 2220 is removed.

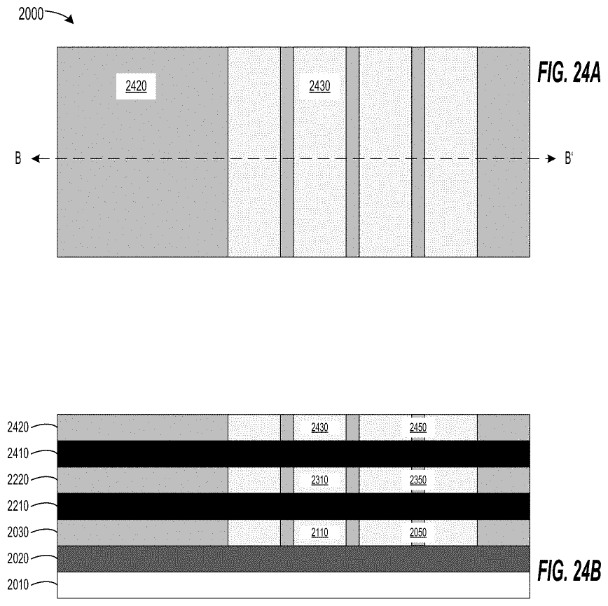

As shown in FIGS. 24A and 24B, similar to the steps shown in FIGS. 22A, 22B, 23A and 23B, a second metal layer 2410 is formed to cover the fourth dielectric layer 2220 and the fifth dielectric layer 2310, another pillars 2450 are formed to support structures that are formed thereover, and a sixth dielectric layer 2420 and a seventh dielectric layer 2430 are formed to cover the second metal layer 2410. In an embodiment, the second metal layer 2410 can be made of the first metal material. In another embodiment, the sixth dielectric layer 2420 and the seventh dielectric layer 2430 can be made of the second dielectric material and the third dielectric material, respectively. In the example embodiment, the semiconductor structure 2000 includes two stacks of metal and dielectric layers, which are vertically stacked over each other. In some embodiments, the semiconductor structure 2000 can include more than two vertical stacks of metal and dielectric layers by repeating the steps shown in FIGS. 22A, 22B, 23A and 23B.

As shown in FIGS. 25A-25D, a hard mask 2510, e.g., made of the second dielectric material, is deposited and formed to cover the sixth dielectric layer 2420 and the seventh dielectric layer 2430. An etch mask or photo resist layer 2520, e.g., a DRAM slicing mask, can then be formed on the hard mask 2510, and the semiconductor structure 2000 is directionally etched through the stacks of dielectric and metal layers to uncover a top surface (e.g., a working surface) of the substrate 2010, thus forming a plurality of semiconductor slices that are separated from one another, each of which has a nanosheet transistor opening area 2530 and a first metal capacitor opening area 2540. In an embodiment, the nanosheet transistor opening area 2530 is used for nanosheet transistors to be formed therein, and includes a central portion 2530a and an extended portion 2530b.

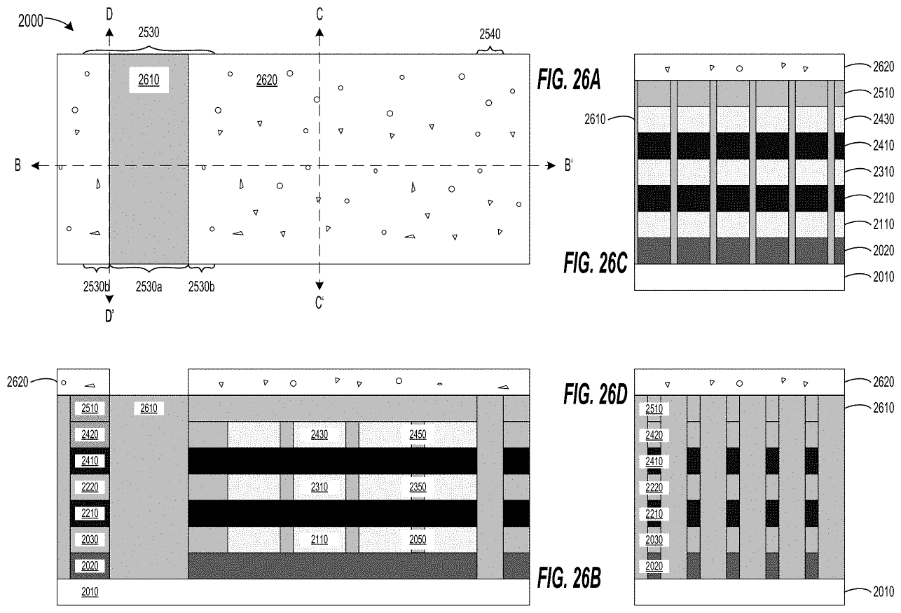

As shown in FIGS. 26A-26D, the etch mask 2520 is stripped off and removed, and the nanosheet transistor opening area 2530 and the first metal capacitor opening area 2540 are filled with an eighth dielectric layer 2610, e.g., made of the second dielectric material. Then, an etch mask 2620, e.g., a DRAM nanosheet mask, can be patterned and formed to cover the hard mask 2510 and a portion of the eighth dielectric layer 2610, with another portion of the eighth dielectric layer 2610 within the central portion 2530a of the nanosheet transistor opening area 2530 uncovered.

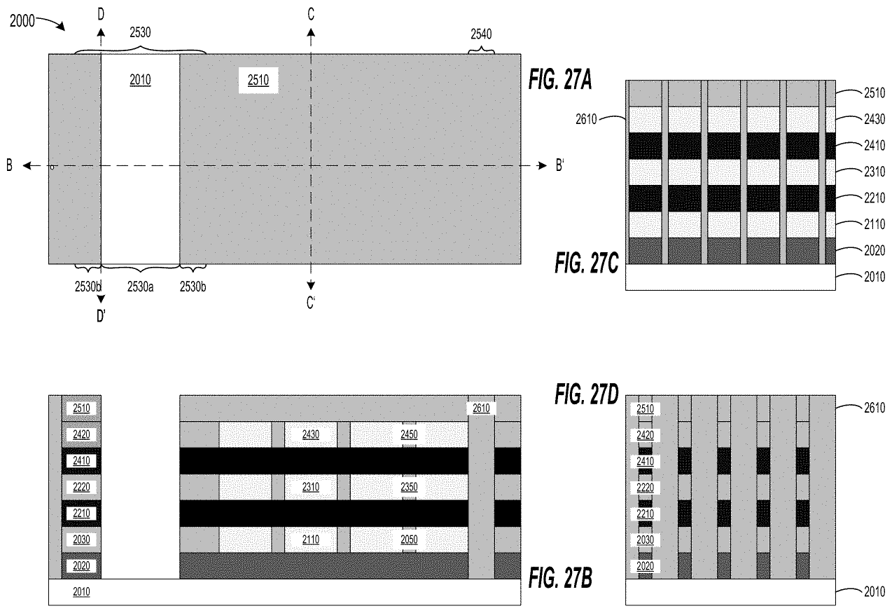

As shown in FIGS. 27A-27D, the eighth dielectric layer 2610 within the central portion 2530a of the nanosheet transistor opening area 2530 is directionally etched until uncovering the top surface of the substrate 2010. Then, the etch mask 2620 can be stripped off and removed.

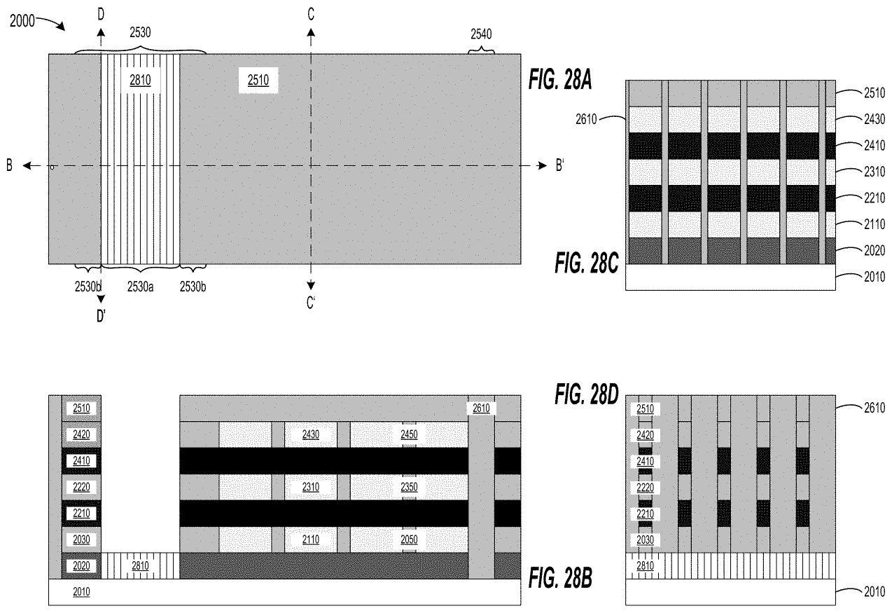

As shown in FIGS. 28A-28D, a first SiGe layer 2810, e.g., made of SiGe90, is epitaxially grown on the uncovered top surface of the lightly doped p-type silicon substrate 2010. In an embodiment, the first SiGe layer 2810 is to cover a lateral surface of the first dielectric layer 2020. The first SiGe layer 2810 is used to replace with an insulation layer in future process steps to keep the nanosheet transistors isolated from the substrate 2010.

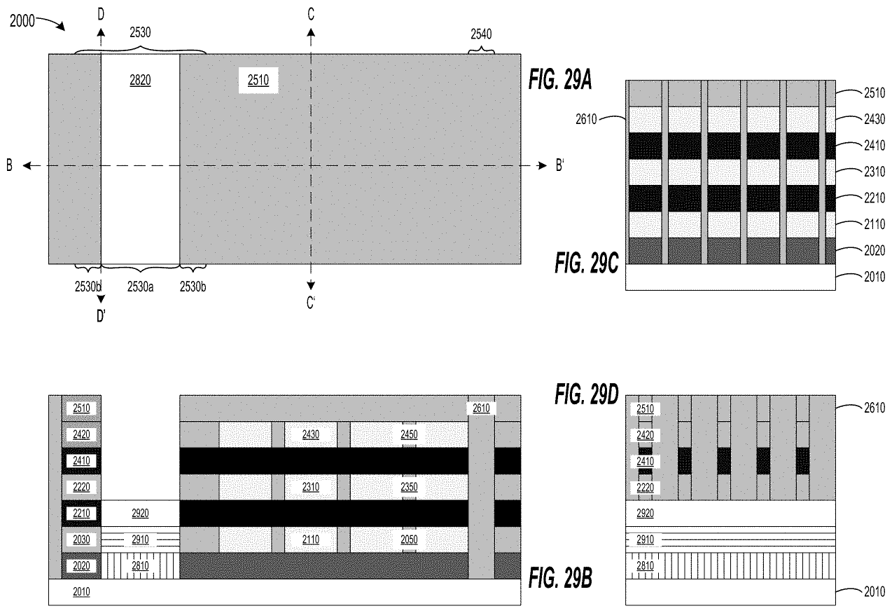

As shown in FIGS. 29A-29D, a second SiGe layer 2910, e.g., made of SiGe30, that is different from the first SiGe layer 2810, is epitaxially grown on the first SiGe layer 2810 to maintain the single crystallinity. The second SiGe layer 2910 and the first SiGe 2810 are etched selectively with respect to each other. In the example embodiment, the second SiGe layer 2910 can be leveled with the second dielectric layer 2030. In some embodiments, the second SiGe layer 2910 can cover a portion of a lateral surface of the second dielectric layer 2030. A first lightly doped p-type silicon layer 2920 can be epitaxially grown on the second SiGe layer 2910. In an embodiment, the first lightly doped p-type silicon layer 2920 has a thickness such that the first lightly doped p-type silicon layer 2920 can cover and touch the first metal layer 2210 entirely. In another embodiment, the first lightly doped p-type silicon layer 2920 can be thicker to further cover a portion of the fourth dielectric layer 2220 and/or a portion of the second dielectric layer 2030.

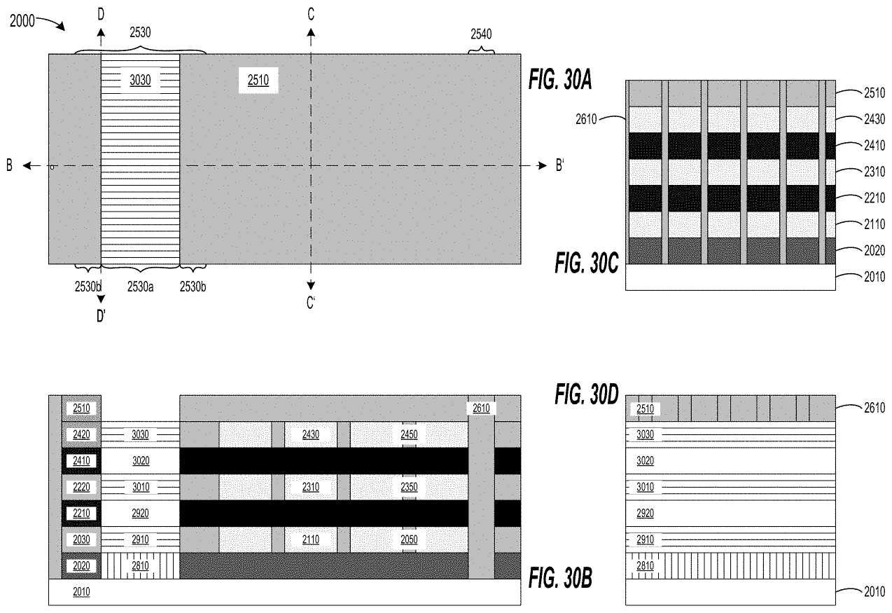

As shown in FIGS. 30A-30D, the epitaxially-grown of SiGe30, lightly doped p-type silicon and SiGe30 layers of the semiconductor structure 2000 can be finished by following the same strategy as illustrated in FIGS. 28A-28D and 29A-29D. For example, a third SiGe layer 3010, e.g., mde of SiGe30, can be deposited and formed on the first lightly doped p-type silicon layer 2920, a second lightly doped p-type silicon layer 3020 can be deposited and formed on the third SiGe layer 3010, and a fourth SiGe layer 3030, e.g., made of SiGe30, can be deposited and formed on the second lightly doped p-type silicon layer 3020. In an embodiment, the third SiGe layer 3010, the second lightly doped p-type silicon layer 3020 and the fourth SiGe layer 3030 can be leveled with the fourth dielectric layer 2220, the second metal layer 2410 and the sixth dielectric layer 2420, respectively. In an embodiment, the second lightly doped p-type silicon layer 3020 has a thickness such that the second lightly doped p-type silicon layer 3020 can cover and touch the second metal layer 2410 entirely. In another embodiment, the second lightly doped p-type silicon layer 3020 can be thicker to further cover a portion of the sixth dielectric layer 2420 and/or a portion of the fourth dielectric layer 2220. For n stacks, the SiGe30 layer and the lightly doped p-type silicon layer can be repeated accordingly. In the example embodiment, the semiconductor structure 2000 includes only one of the SiGe90, i.e., the first SiGe layer 2810, which is formed at the bottom most within the nanosheet transistor opening area 2530. In an embodiment, the semiconductor structure 2000 can include more than one of the SiGe90 and one or more than one of the SiGe90 can be inserted in between the SiGe30 if any discontinuity is needed in the semiconductor structure 2000.

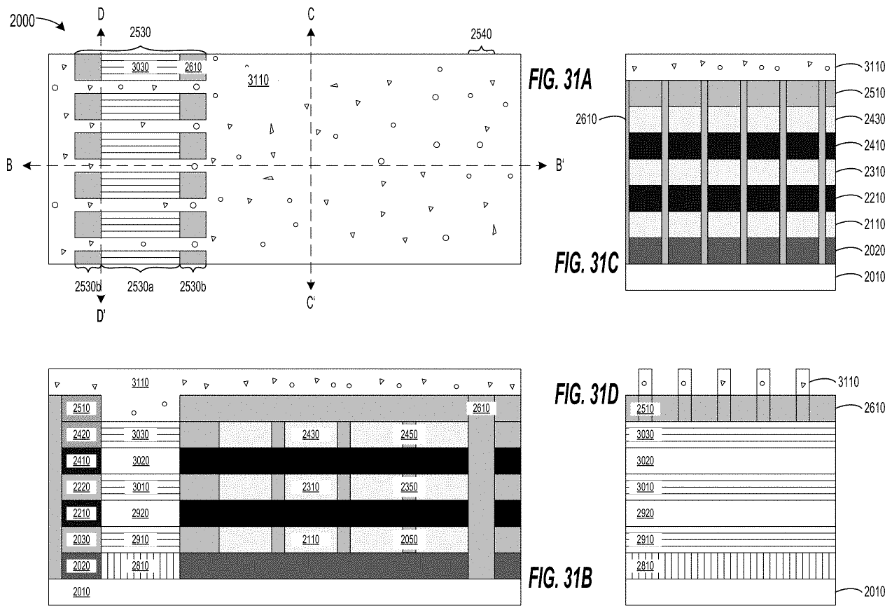

As shown in FIGS. 31A-31D, an etch mask or photo resist layer 3110, e.g., a DRAM slicing mask, is formed on the hard mask 2510 and the eighth dielectric layer 2610, with the nanosheet transistor opening area 2530, including the central portion 2530a and the extended portion 2530b, uncovered.

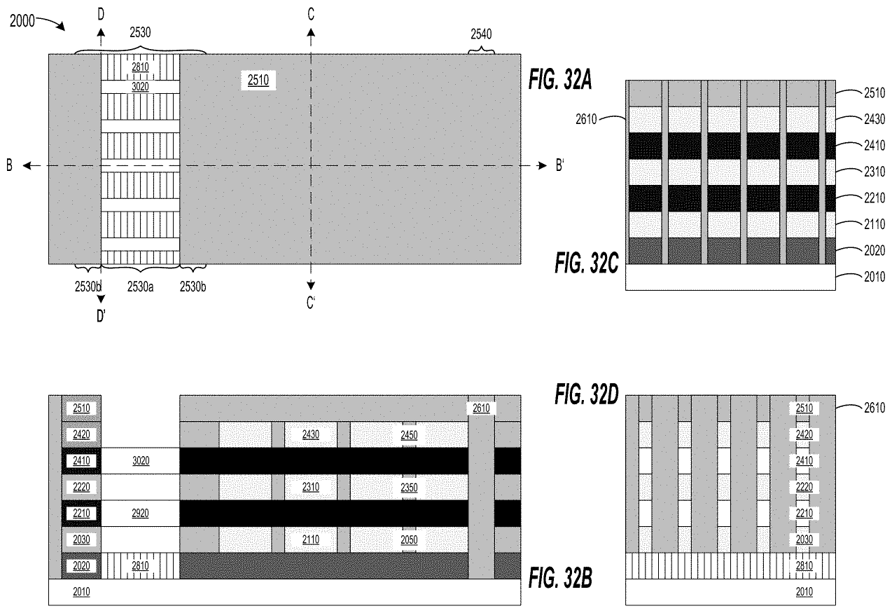

As shown in FIGS. 32A-32D, the semiconductor structure 2000 is directionally etched to remove the SiGe30, i.e., the second SiGe layer 2910, the third SiGe layer 3010 and the fourth SiGe layer 3030, with the first lightly doped p-type silicon layer 2920, the second lightly doped p-type silicon layer 3020, and the SiGe90, i.e., the first SiGe layer 2810, intact, which are etched selectively with respect to the SiGe30. In an embodiment, for each suitability the final SiGe30 needs not be etched all the way. For example, partial etching is enough to access the SiGe30. In an embodiment, the SiGe30 can be removed by vapor-phase isotropic etching.

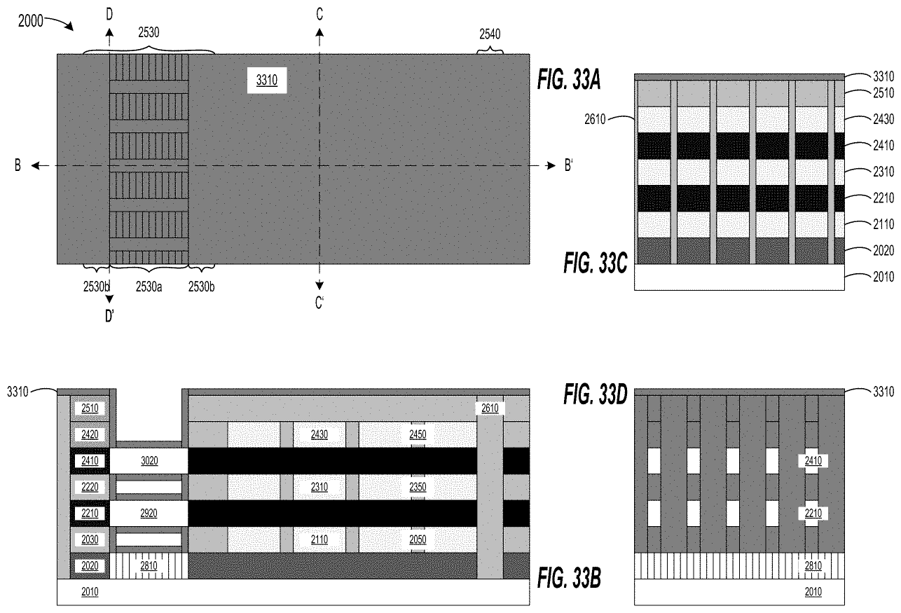

As shown in FIGS. 33A-33D, a thin first high-k dielectric layer 3310 is formed in a conformal deposition process to surround the first lightly doped p-type silicon layer 2920 and the second lightly doped p-type silicon layer 3020, which are used as channels of the nanosheet transistors of the semiconductor structure 2000. The ALD process can provide ultra-thin nano-layers in a precise manner on the first lightly doped p-type silicon layer 2920 and the second lightly doped p-type silicon layer 3020.

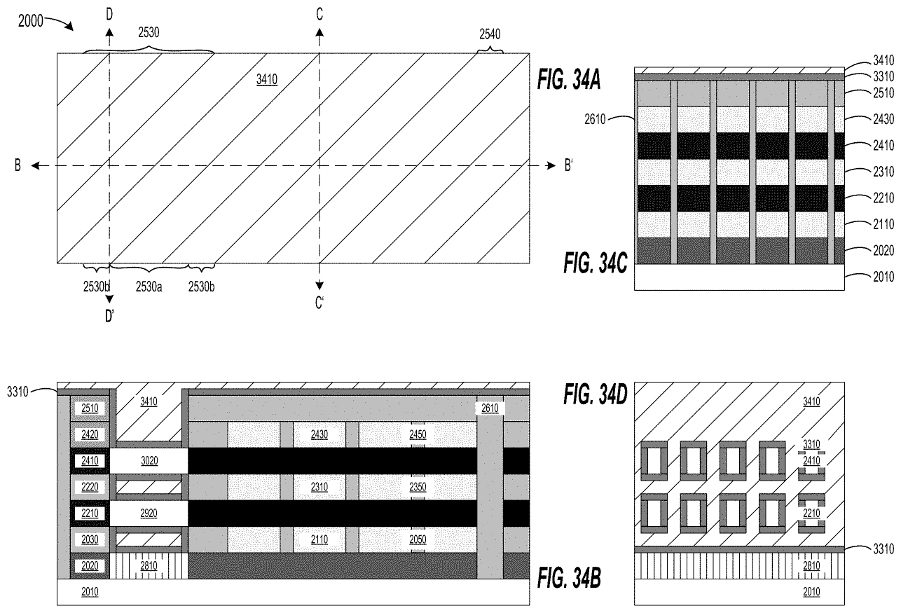

As shown in FIGS. 34A-34D, a third metal layer 3410 is deposited and formed on the first high-k dielectric layer 3310. In an embodiment, the third metal layer 3410 can be made of a third metal material that is different from the first metal material.

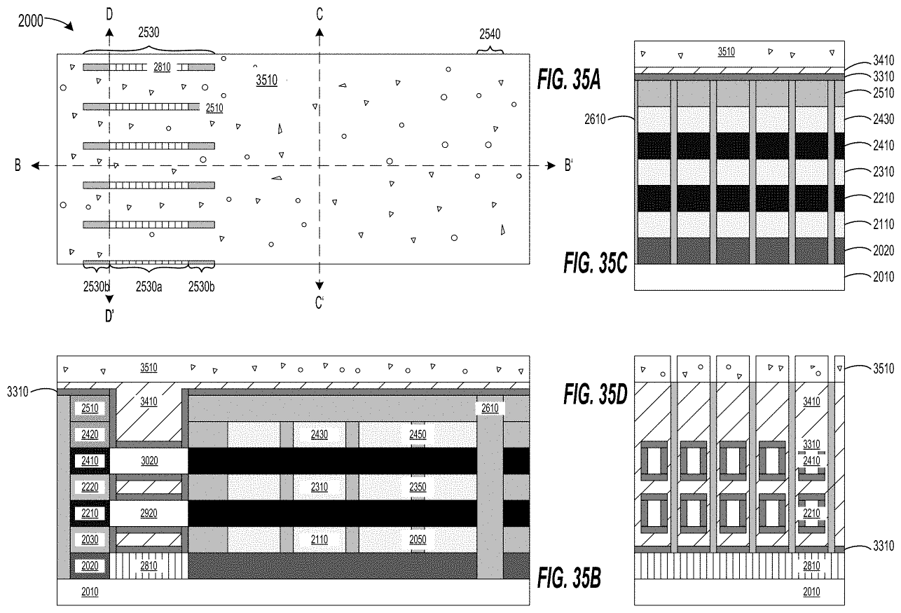

As shown in FIGS. 35A-35D, an etch mask or photo resist layer 3510, e.g., a DRAM slicing mask, is formed on the third metal layer 3410, and the semiconductor structure 2000 is directionally etched through the third metal layer 3410 and the first high-k dielectric layer 3310 to uncover the SiGe90, i.e., the first SiGe layer 2810. This etch opens access to the first SiGe layer 2810.

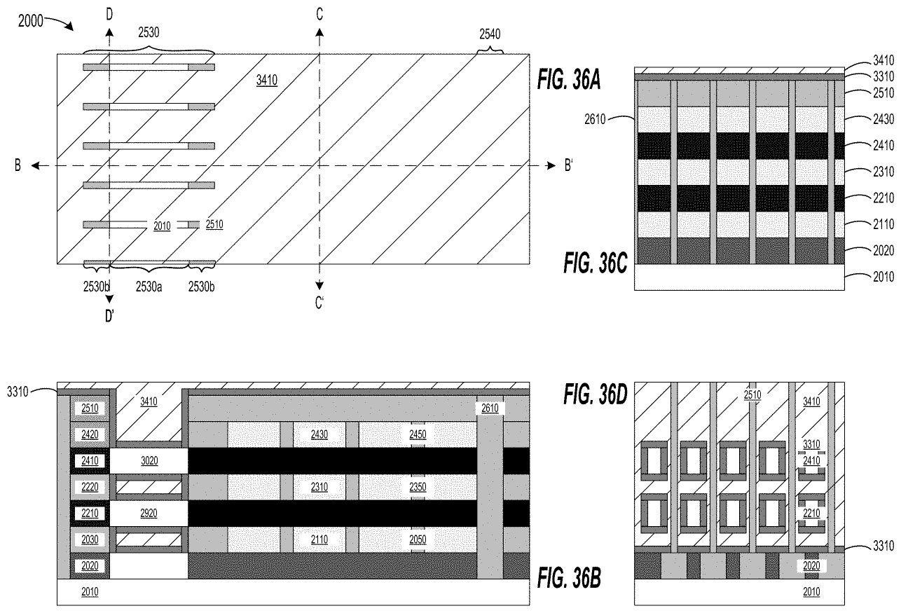

As shown in FIGS. 36A-36D, the SiGe90, i.e., the first SiGe layer 2810, is etched and removed. The etch mask 3510 can also be stripped off and removed.

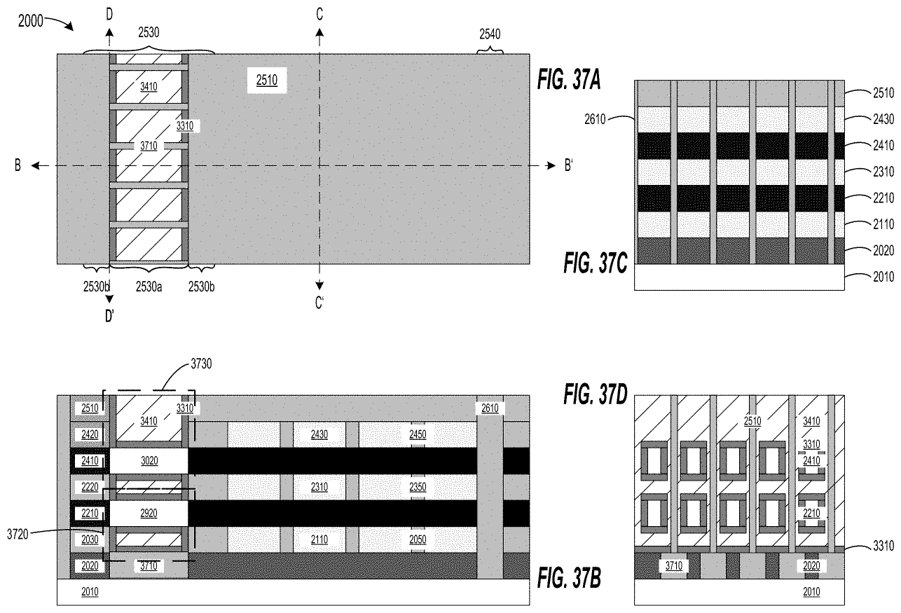

As shown in FIGS. 37A-37D, a ninth dielectric layer 3710, e.g., made of the second dielectric material, fills a space that is generated after the SiGe90, i.e., the first SiGe layer 2810, is removed. The CMP process can then be performed to planarize the ninth dielectric layer 3710, the third metal layer 3410 and the first high-k dielectric layer 3310.

The semiconductor structure 2000 thus fabricated can include a (gate-all-around (GAA)) lower (or first) nanosheet transistor 3720 and an (GAA) upper (or second) nanosheet transistor 3730 that is stacked over the lower nanosheet transistor 3720. The lower nanosheet transistor 3720 includes a channel, i.e., the first lightly doped p-type silicon layer 2920, a gate region, i.e., the first high-k dielectric layer 3310, that surrounds the channel and is surrounded by the third metal layer 3410, which can act as a gate electrode of the lower nanosheet transistor 3720, and source/drain (S/D) regions, i.e., two ends of the first lightly doped p-type silicon layer 2920, that are electrically connected to the first metal layer 2210, which can act as S/D electrodes of the lower nanosheet transistor 3720. The ninth dielectric layer 3710 can insulate the lower nanosheet transistor 3720 from the substrate 2010. The upper nanosheet transistor 3730 includes a channel, i.e., the second lightly doped p-type silicon layer 3020, a gate region, i.e., the first high-k dielectric layer 3310, that surrounds the channel and is surrounded by the third metal layer 3410, which can act as a gate electrode of the upper nanosheet transistor 3730, and source/drain regions, i.e., two ends of the second lightly doped p-type silicon layer 3020, that are electrically connected to the second metal layer 2410, which can act as S/D electrodes of the upper nanosheet transistor 3730. The gate regions of the lower nanosheet transistor 3720 and the upper nanosheet transistor 3730 are shorted by the third metal layer 3410.

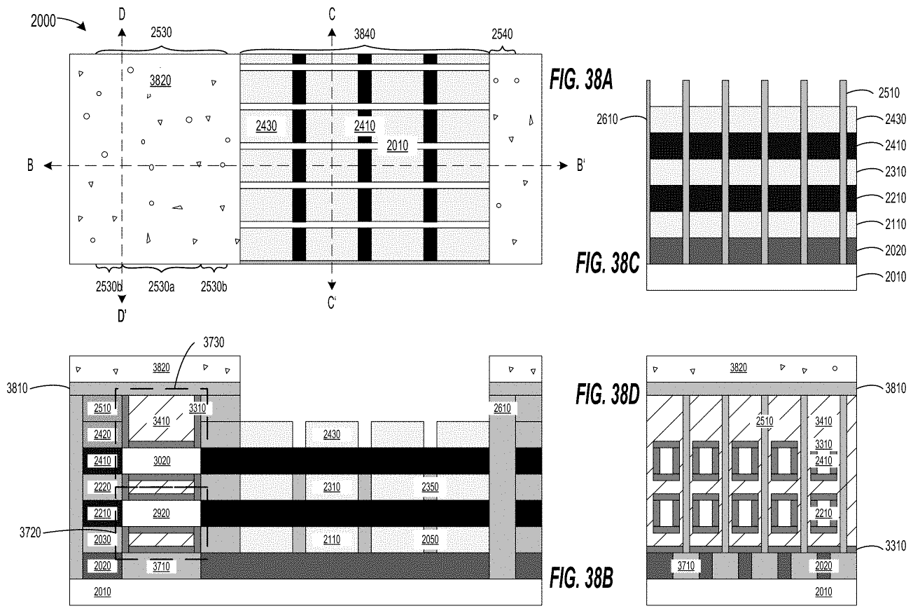

As shown in FIGS. 38A-38D, a hard mask or photo resist layer 3810, e.g., made of the second dielectric material, is formed on the semiconductor structure 2000 to cover the hard mask 2510, the third metal layer 3410 and the first high-k dielectric layer 3310. An etch mask 3820, e.g., a DRAM capacitor mask, can be formed on the hard mask 3810, with a portion of the hard mask 3810 uncovered within a second metal capacitor opening area 3840 that is between the nanosheet transistor opening area 2530 and the first metal capacitor opening area 2540 and is spaced away from the first metal capacitor opening area 2540 at a distance. In another embodiment, the second metal capacitor opening area 3840 is used for metal capacitors to be formed therein, which can be shorted to a common ground. In an embodiment, the second metal capacitor opening area 3840 is wider than the nanosheet transistor opening area 2530 for the metal capacitors of the semiconductor structure 2000 to have a higher capacitor value. Then, the semiconductor structure 2000 within the second metal capacitor opening area 3840 is directionally etched to etch the hard mask 3810, the hard mask 2510 and the sixth dielectric layer 2420 (i.e., the another pillars 2450), all of which are made of the second dielectric material, until uncovering the top surface of the substrate 110.

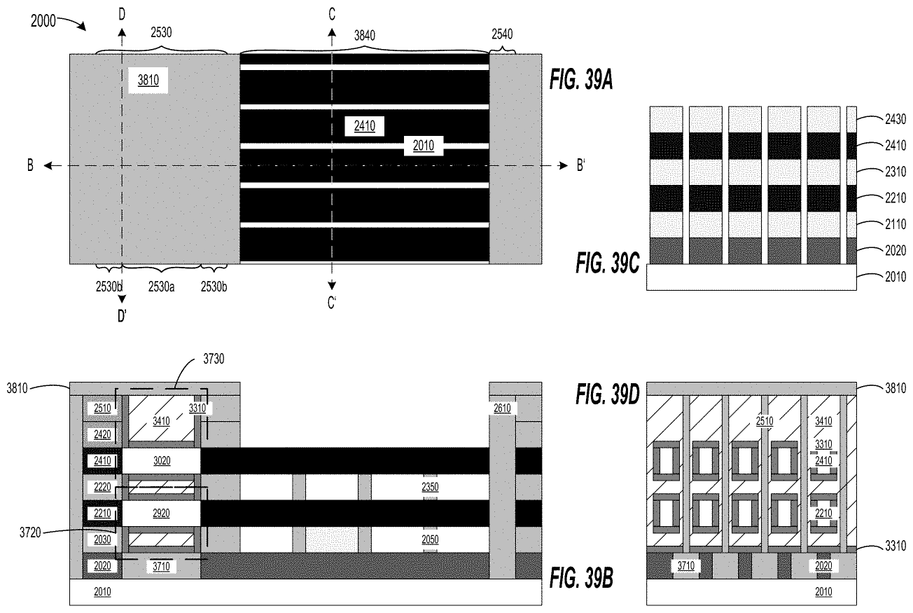

As shown in FIGS. 39A-39D, the etch mask 3820 is stripped off and removed, and the seventh dielectric layer 2430, fifth dielectric layer 2310 and the third dielectric layer 2110, all of which are made of the third dielectric material, can be etched and removed.

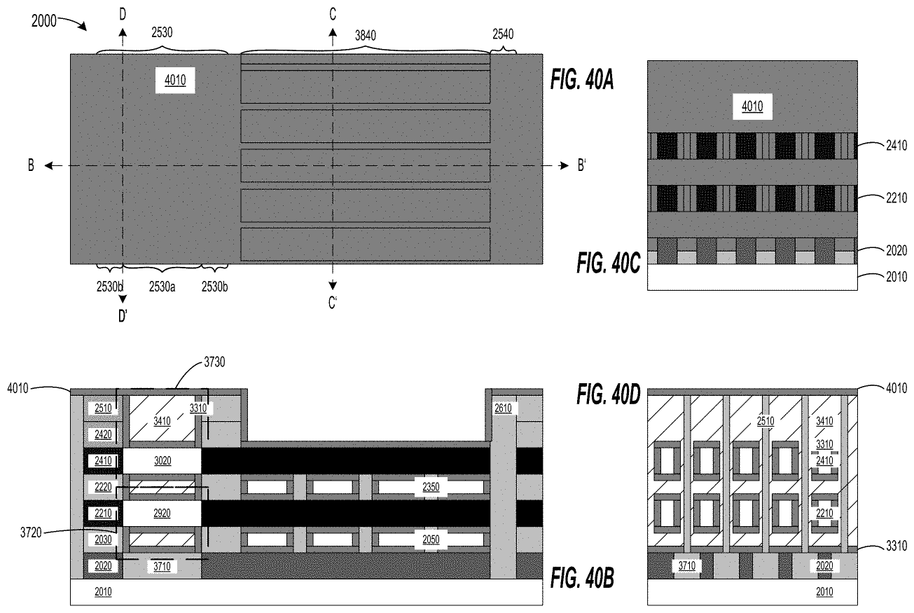

As shown in FIGS. 40A-40D, the hard mask 3810 is stripped off and removed, and a thin second high-k dielectric layer 4010 is formed in a conformal deposition process to surround the first metal layer 2210 and the second metal layer 2410 within the second metal capacitor opening area 3840. The ALD process can provide ultra-thin nano-layers in a precise manner on the first metal layer 2210 and the second metal layer 2410.

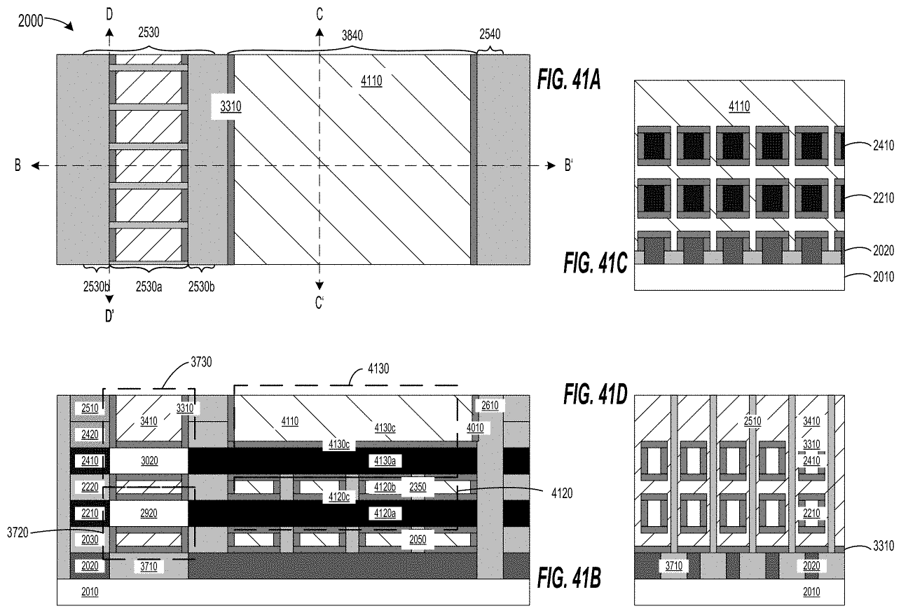

As shown in FIGS. 41A-41D, a fourth metal layer 4110 can be deposited and formed on the second high-k dielectric layer 4010. The fourth metal layer 4110 can be made of a second metal material that is different from the first and third metal materials. The CMP process can then be performed to planarize the fourth metal layer 4110 and the second high-k dielectric layer 4010.

The semiconductor structure 2000 thus further fabricated can further include a lower metal capacitor 4120 and an upper metal capacitor 4130 that is stacked over the lower metal capacitor 4120. The lower metal capacitor 4120 is electrically connected to the lower nanosheet transistor 3720 horizontally, and includes a first lower metal plate 4120a, i.e., the first metal layer 2210, that is electrically connected to the S/D electrodes of the lower nanosheet transistor 3720, a second lower metal plate (or non-terminal metal plate) 4120b, i.e., the fourth metal layer 4110, that is isolated by the fourth dielectric layer 2220 from the lower nanosheet transistor 3720 and is not electrically connected to the lower nanosheet transistor 3720, and a lower dielectric layer 4120c, i.e., the second high-k dielectric layer 4010, that is sandwiched between the first lower metal plate 4120a and the second lower metal plate 4120b for storing electrical charges flowing from the lower nanosheet transistor 3720. The upper metal capacitor 4130 is electrically connected to the upper nanosheet transistor 3730 horizontally, and includes a first upper metal plate 4130a, i.e., the second metal layer 2410, that is electrically connected to the S/D electrodes of the upper nanosheet transistor 3730, a second upper metal plate (or non-terminal metal plate) 4130b, i.e., the fourth metal layer 4110, that is isolated by the sixth dielectric layer 2420 from the upper nanosheet transistor 3730 and is not electrically connected to the upper nanosheet transistor 3730, and an upper dielectric layer 4130c, i.e., the second high-k dielectric layer 4010, that is sandwiched between the first upper metal plate 4130a and the second upper metal plate 4130b for storing electrical charges flowing from the upper nanosheet transistor 3730. The non-terminal metal plates of the lower metal capacitor 4120 and the upper metal capacitor 4130, i.e., the second lower metal plate 4120b and the second upper metal plate 4130b, can be electrically connected, e.g., by the fourth metal layer 4110, and have common ground connection and be shorted to a common ground.

Since the semiconductor structures 100 and 2000 include the lower nanosheet transistor 1520/3720 and the upper nanosheet transistor 1530/3731 are single crystal silicon, high performance Idₛₐₜ and robust Id_{off} can be achieved. As the semiconductor structures 100 and 2000 include DRAMs that are vertically stacked over one another, a significant improvement in circuit density can be obtained.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the present disclosure are not intended to be limiting. Rather, any limitations to embodiments of the present disclosure are presented in the following claims.

What is claimed is:

1. A method for fabricating a semiconductor structure, comprising:
forming over a substrate a lower stack of alternating metal and dielectric layers that are parallel to a top surface of the substrate;
forming an upper stack of alternating metal and dielectric layers that are parallel to the top surface of the substrate, the upper stack vertically stacked over the lower stack;
forming a first opening through the upper stack and the lower stack until uncovering a top surface of the substrate; and
forming within the first opening a lower transistor that is insulated from the substrate and an upper transistor that is vertically stacked over the lower transistor, the lower transistor including a lower channel that is elongated horizontally and is in-plane with a first lower metal layer of the lower stack, and the upper transistor including an upper channel that is elongated horizontally and is in-plane with a first upper metal layer of the upper stack;
removing the dielectric layers of the upper stack and the lower stack within a metal capacitor opening area that is separated from the first opening at a distance to uncover the first lower metal layer of the lower stack and the first upper metal layer of the upper stack that are a first lower metal plate of a lower metal capacitor and a first upper metal plate of an upper metal capacitor, respectively;
surrounding the first lower metal plate and the first upper metal plate with a dielectric layer; and
surrounding the dielectric layer with a first metal material that forms a second lower metal plate of the lower metal capacitor and a second upper metal plate of the upper metal capacitor.

2. The method of claim 1, wherein the second lower metal plate of the lower metal capacitor and the second upper metal plate of the upper metal capacitor are electrically connected to each other.

3. The method of claim 1, wherein the lower transistor further includes a lower gate region that surrounds the lower channel, and the upper transistor further includes an upper gate region that surrounds the upper channel.

4. The method of claim 3, wherein the upper gate region and the lower gate region are electrically connected to each other.

5. The method of claim 4, wherein the lower transistor and the upper transistor are formed by:
epitaxially growing a first single crystal material on the substrate within the first opening;
epitaxially growing a second single crystal material over the first single crystal material to maintain single crystallinity, the second single crystal material being etched selectively with respect to the first single crystal material;
epitaxially growing the lower channel of the lower transistor over the second single crystal material, the lower channel covering a lateral side of the first lower metal layer of the lower stack;
epitaxially growing a third single crystal material over the lower channel, the third single crystal material being etched selectively with respect to the first single crystal material;
epitaxially growing the upper channel of the upper transistor over the third single crystal material, the upper channel covering a lateral side of the first upper metal layer of the upper stack;
epitaxially growing a fourth single crystal material over the upper channel, the fourth single crystal material being etched selectively with respect to the first single crystal material;
etching and removing the first single crystal material and replacing with an insulating material;
etching the second single crystal material, the third single crystal material and the fourth single crystal material to uncover the lower channel and the upper channel;
forming the lower gate region and the upper gate region that surround the lower channel and the upper channel, respectively; and
filling the first opening with a second metal material.

6. The method of claim 5, wherein the second single crystal material, the third single crystal material and the fourth single crystal material are a same.

7. The method of claim 6, wherein the second single crystal material includes SiGe30.

8. The method of claim 5, wherein the first single crystal material includes SiGe90.

9. The method of claim 1, further comprising:
forming one or more lower pillars that separate the second lower metal plate of the lower metal capacitor.

10. The method of claim 9, wherein the lower pillars are formed by:
removing a portion of a lower dielectric layer of the lower stack that is under the first lower metal layer; and
filling a dielectric material in a space that is generated after the portion of the lower dielectric layer of the lower stack is removed, the dielectric material being etched selectively with respect to the lower dielectric layer of the lower stack.

11. The method of claim 1, wherein the lower transistor is narrower than the lower metal capacitor horizontally.

12. A semiconductor structure, comprising:
a lower transistor including a lower channel that is elongated horizontally;
an upper transistor vertically stacked over the lower transistor and including an upper channel that is elongated horizontally;
a lower metal capacitor electrically connected to and horizontally elongated from the lower transistor, the lower metal capacitor including a first lower metal plate, a lower dielectric layer that surrounds the first lower metal plate, and a second lower metal plate that surrounds the lower dielectric layer; and
an upper metal capacitor vertically stacked over the lower metal capacitor and electrically connected to and horizontally elongated from the upper transistor, the upper metal capacitor including a first upper metal plate, an upper dielectric layer that surrounds the first upper metal plate, and a second upper metal plate that surrounds the upper dielectric layer.

13. The semiconductor structure of claim 12, wherein the first lower metal plate of the lower metal capacitor is electrically connected to and in-plane with the lower channel of the lower transistor, and the first upper metal plate of the upper metal capacitor is electrically connected to and in-plane with the upper channel of the upper transistor.

14. The semiconductor structure of claim 12, wherein the second upper metal plate and the second lower metal plate are electrically connected to each other.

15. The semiconductor structure of claim 12, wherein the lower transistor further includes a lower gate region that surrounds the lower channel, and the upper transistor further includes an upper gate region that surrounds the upper channel.

16. The semiconductor structure of claim 15, wherein the upper gate region and the lower gate region are electrically connected to each other.

17. The semiconductor structure of claim 16, further comprising:
a metal layer that surrounds the lower gate region of the lower transistor and the upper gate region of the upper transistor.

18. The semiconductor structure of claim 15, wherein the lower dielectric layer of the lower metal capacitor is in-plane with the lower gate region of the lower transistor, and the upper dielectric layer of the upper metal capacitor is in-plane with the upper gate region of the upper transistor.

19. The semiconductor structure of claim 12, wherein the lower metal capacitor further includes one or more lower pillars that separate the second lower metal plate.

20. The semiconductor structure of claim 12, wherein the lower transistor is narrower than the lower metal capacitor horizontally.
